(19) United States
(12) Patent Application Publication
(10) Pub. No.: US 2011/0001251 A1
(43) Pub. Date: Jan. 6, 2011

(54) ADHESIVE COMPOSITION, BONDING MEMBER USING THE ADHESIVE COMPOSITION, SUPPORT MEMBER FOR SEMICONDUCTOR MOUNTING, SEMICONDUCTOR DEVICE, AND PROCESSES FOR PRODUCING THESE

(76) Inventors: Yutaka Gou, Ibaraki (JP); Kazuhiro Miyauchi, Ibaraki (JP); Takashi Inoue, Yamagata (JP); Atsushi Takahara, Fukuoka (JP); Hiroshi Jinnai, Kyoto (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/667,398

(22) PCT Filed: Jul. 3, 2008
(86) PCT No.: PCT/JP2008/062088

§ 371 Date: Dec. 31, 2009

(30) Foreign Application Priority Data
Jul. 3, 2007 (JP) 2007-175087
Jul. 26, 2007 (JP) 2007-194498
Jul. 31, 2007 (JP) 2007-198920
Aug. 1, 2007 (JP) 2007-200686

(51) Int. Cl. H01L 23/52; H01L 21/60; C09J 163/00; B32B 37/12

(52) U.S. Cl. 257/783; 438/118; 525/119; 156/330; 257/E23.141; 257/E21.506

(57) ABSTRACT

Disclosed is an adhesive composition, comprising, as essential components, a thermosetting resin component A and a high-molecular component B which are evenly compatible and miscible with each other at a temperature of 5 to 40° C. without being separated from each other, and a curing agent component C,

wherein after the adhesive composition comes into contact with an adherend and after the thermosetting resin component A is cured, the thermosetting resin component A is separated, in the adhesive composition, into particulate structures wherein the concentration of the thermosetting resin component A is larger than that in the surrounding of the particulate structures, and further the particulate structures are formed in a larger amount near a surface of the composition which contacts the adherend than inside the adhesive composition. The adhesive composition can be used in thin-film bonding. it is possible to provide an adhesive composition excellent in heat resistance, crack resistance, adhesive property, and exudation resistance, which is property that the adhesive less exudes.

### TECHNICAL FIELD

The present invention relates to an adhesive composition, a process for producing the composition, a bonding member using the adhesive composition, a process for producing the bonding member, a support member for semiconductor mounting, a process for producing the support member, a semiconductor device, and a process for producing the semiconductor device.

### BACKGROUND ART

Any single polymeric material does not simultaneously exhibit conflicting properties with ease; thus, it is important that polymers are blended with each other, thereby improving the properties. In many cases, about a polymeric blend material, the function of the material is heightened by controlling the phase separation structure of the blend material.

Any monomer or oligomer for thermosetting resin is compatible with many polymeric components. When a system in such a single phase state is thermally cured, the molecular weight of the thermosetting resin is increased so that a two-phase region is enlarged in the phase diagram and the compatible region is decreased therein, as expected from Flory-Huggins' theory.

According to, for example, Non-Patent Document 1, the phase diagram of epoxy resin and butadiene/acrylonitrile copolymer (CTBN) shows an upper limit critical solution temperature (UCST) type. As they are caused to react with each other, the two-phase region thereof is gradually shifted toward lower temperatures, so as to come into a two-phase region. In short, by the reaction, spinodal decomposition is induced so that phase separation is caused.

Such a reaction-inducing type phase decomposition is said to be a useful method capable of controlling the phase structure by freezing the structure in various steps in the phase decomposition.

For adhesive material used in semiconductor packages or wiring, an adhesive composition is generally used which is a thermosetting alloy made of a thermosetting resin and a polymeric component. Examples thereof include an adhesive described in Patent Document 1 and containing an acrylic resin, an epoxy resin, a polyisocyanate, and an inorganic filler; and an adhesive described in Patent Document 2 and containing an acrylic resin, an epoxy resin, primary amine terminated compounds having a urethane bond in the molecule thereof, and an inorganic filler.

These adhesives can satisfy required properties, such as handleability, tackiness necessary for adhesion, and softness before they are cured, and they can satisfy excellent adhesive force, electrical insulation reliability, and thermal stress absorbance after they are cured.

However, the adhesives are largely deteriorated when they are subjected to a humidity resistance test under sever conditions for PCT (pressure cooker test) treatment or the like.

The adhesives have drawbacks that the adhesive force is largely lowered after they are treated at high temperature over a long period and they are poor in electrolytic corrosion resistance, and other drawbacks. The adhesives are largely deteriorated, in particular, when they are subjected to a humidity resistance test under sever conditions for PCT (pressure cooker test) treatment, which is used to evaluate the reliability of semiconductor-related components, or the like.

As electronic instruments have been developed in recent years, the mounting density of electronic components has been made high. Thus, the adoption of the following new type packaging method has been starting: packaging method for a semiconductor package having a size substantially equal to a semiconductor chip, which is called a chip scale package or chip size package (hereinafter referred to as a CSP); packaging method for bare chip mounting of semiconductors; and the like.

Furthermore, instead of conventional packaging wherein a single chip is mounted in a single package, the adoption of the following has also been starting: packaging wherein plural chips are mounted, in particular, packaging wherein chips are vertically laminated so that the density can be made high. In such a situation, thin-film bonding has been becoming necessary when chips, a wiring board, and the like are bonded.

The thin-film bonding has advantages that the bonding is high in heat conductivity, low in energy absorption, weight and costs, and excellent in recyclability, and other advantages; however, it is known that the following adverse effects are involved: a fall in adhesive force, a fall in heat resistance, poor bonding onto a rough surface, a fall in thermal stress relaxation, and the like.

Non-Patent Document 1: Polymer, 1989, vol. 30, pp. 1839-1844

Patent Document 1: JP-A No. 60-243180

Patent Document 2: JP-A No. 61-138680

### DISCLOSURE OF THE INVENTION

An object of the invention is to provide an adhesive composition that can be used for thin-film bonding wherein an adhesive layer of 30 μm or less thickness, which is generally said not to be easily bonded, and that is excellent in heat resistance, crack resistance, adhesive property, and exudation resistance, which is a property that the adhesive less exudes. Another object thereof is to provide a bonding member using the adhesive composition, a process for producing the bonding member, a support member for semiconductor mounting, a process for producing the support member, a semiconductor device, and a process for producing the semiconductor device.

In order to cope with these adverse effects based on the thin-film bonding, the inventors have conceived an idea that two points produce a large effect on the bonding. The points are specifically (1) a phase separation structure of the vicinity of a composition surface contacting an adherend after the composition is cured; and (2) a phase separation structure in a sea phase after the composition is cured.

The inventors have presumed that the matter of preparing an adhesive composition wherein these can be controlled is a useful manner. It has been forecasted that such phase separation structures produce an effect of preventing cracks when the adhesive composition is broken, and an effect of preventing a matter that local breakdown based on irregularity in the phase structures, or based on defects in the phase structures continue. Thus, the effects have been expected, in particular, for the thin-film bonding. Furthermore, since the stress relaxation effect of the material on the basis of thermal hysteresis also works, an expectation of a large improvement in dynamic properties has been growing.

The inventors have made eager investigations for solving the problems, so as to find out that in the following case about an adhesive composition comprising, as essential components, a thermosetting resin component A and a high-molecular component B which are evenly compatible and miscible with each other at or near room temperature (5 to 40° C.) without being separated from each other, and a curing agent component C, a high-function adhesive film having excellent dynamic properties is obtained: a case where when the thermosetting resin component A is cured after the adhesive composition comes into contact with an adherend, the thermosetting resin component A is separated into particulate structures wherein the concentration of the thermosetting resin component A is larger than that in the surrounding of the particulate structures, and further the particulate structures are formed in a larger amount near a surface of the composition which contacts the adherend than inside the composition. Thus, the inventors have made the invention.

Furthermore, the inventors have found out that also in the following case about the adhesive composition, a high-function adhesive film having excellent dynamic properties is obtained: a case where when the thermosetting resin component A is cured after the composition comes into contact with an adherend, the thermosetting resin component A is separated into particulate structures wherein the concentration of the thermosetting resin component A is larger than that in the surrounding of the structures; the particulate structures are formed in a larger amount near a surface of the composition which contacts the adherend than inside the composition; and a region where the concentration of the high-molecular component B is higher, the region being around the particulate structures formed near the composition surface contacting the adherend, has a nature that when the adherend is peeled, pores are generated partially in the region by expansion stress, and/or the particulate structures formed near the composition surface contacting the adherend have a nature that when the adherend is peeled, the particulate structures partially undergo plastic deformation so as to be divided into fine fragments. Thus, the invention has been made.

The inventors have found out that also in the following case about the adhesive composition, a high-function adhesive film having excellent dynamic properties is obtained: a case where separation is made into the following in the adhesive composition when the adhesive composition comes into contact with an adherend and subsequently the thermosetting resin component A is cured:

particulate structures a1 which are higher in the concentration of the thermosetting resin component A than the surrounding of the particulate structures a1, and have an average diameter D1;
particulate structures a2 which are present in the particulate structures a1, have an average diameter D2 smaller than the average diameter D1, and are higher in the concentration of the thermosetting resin component A than the particulate structures a1;
a region b3 which is present in the particulate structures a1, is higher in the concentration of the high-molecular component B than the particulate structures a1, and is different region from the particulate structures a2;
a region b2 which is higher in the concentration of the high-molecular component B than the particulate structures a1; and
particulate structures a4 which have an average diameter D6 smaller than the average diameter D1, and are higher in the concentration of the thermosetting resin component A than the region b2. Thus, the invention has been made.

The inventors have found out that also in the following case about the adhesive composition, a high-function adhesive film having excellent dynamic properties is obtained: a case where separation is made into the following in the adhesive composition when the adhesive composition comes into contact with an adherend and subsequently the thermosetting resin component A is cured:

particulate structures a1 which are higher in the concentration of the thermosetting resin component A than the surrounding of the particulate structures a1., and have an average diameter D1;
a region b2 which is higher in the concentration of the high-molecular component B than the particulate structures a1; and
particle-continued structures and/or co-continuous-phase structures a3 which are higher in the concentration of the thermosetting resin component A than the region b2, and have an average diameter D3 smaller than the average diameter D1 of the particulate structures a1. Thus, the invention has been made.

Accordingly, the invention is as follows:

(1) An adhesive composition, comprising, as essential components, a thermosetting resin component A and a high-molecular component B which are evenly compatible and miscible with each other at a temperature of 5 to 40° C. without being separated from each other, and a curing agent component C,

wherein after the adhesive composition comes into contact with an adherend and after the thermosetting resin component A is cured, the thermosetting resin component A is separated, in the adhesive composition, into particulate structures wherein the concentration of the thermosetting resin component A is larger than that in the surrounding of the particulate structures, and further the particulate structures are formed in a larger amount near a surface of the composition which contacts the adherend than inside the adhesive composition.

(2) An adhesive composition, comprising, as essential components, a thermosetting resin component A and a high-molecular component B which are evenly compatible and miscible with each other at a temperature of 5 to 40° C. without being separated from each other, and a curing agent component C,

wherein after the adhesive composition comes into contact with an adherend and after the thermosetting resin component A is cured, the thermosetting resin component A is separated, in the adhesive composition, into particulate structures wherein the concentration of the thermosetting resin component A is larger than that in the surrounding of the particulate structures, the particulate structures are formed in a larger amount near a surface of the composition which contacts the adherend than inside the adhesive composition, and

a region where the concentration of the high-molecular component B is higher, the region being around the particulate structures formed near the composition surface contacting the adherend, has a nature that when the adherend is peeled, pores are generated partially in the region by expansion stress.

(3) An adhesive composition, comprising, as essential components, a thermosetting resin component A and a high-molecular component B which are evenly compatible and miscible with each other at a temperature of 5 to 40° C. without being separated from each other, and a curing agent component C,

wherein after the adhesive composition comes into contact with an adherend and after the thermosetting resin component A is cured, the thermosetting resin component A is separated, in the adhesive composition, into particulate structures wherein the concentration of the thermosetting resin component A is larger than that in the surrounding of the particulate structures, the particulate structures are formed in a larger amount near a surface of the composition which contacts the adherend than inside the adhesive composition, and

the particulate structures formed near the composition surface contacting the adherend have a nature that when the adherend is peeled, the particulate structures partially undergo plastic deformation so as to be divided into fine fragments.

(4) The adhesive composition according to item (2) or (3), wherein a region where the concentration of the high-molecular component B is higher, the region being around the particulate structures formed near the composition surface contacting the adherend, has a nature that when the adherend is peeled, pores are generated partially in the region by expansion stress, and the particulate structures formed near the composition surface contacting the adherend have a nature that when the adherend is peeled, the particulate structures partially undergo plastic deformation so as to be divided into fine fragments.

(5) The adhesive composition according to any one of items (1) to (4), having the following relationship when the area fraction of the particulate structures to other regions in a section which is orthogonal to the adherend after the curing is represented by AF, the average diameter of the particulate structures is represented by D1, the area fraction of a region having distances of 0 to D1. from the composition surface contacting the adherend is represented by AFT, and the area fraction of a region having distances of D1 to D1×2 from the composition surface contacting the adherend is represented by AF2: AF1/AF2>1.05.

(6) The adhesive composition according to any one of items (1) to (5), wherein after the adhesive composition contacts the adherend and before the composition is cured, the thermosetting resin component A and/or the curing agent component C, is/are higher in concentration in the region having distances of 0 to D1 which is the average diameter of the particulate structures from the composition surface contacting the adherend than in the region having distances of D1 to D1×2 from the composition surface contacting the adherend.

(7) An adhesive composition comprising, as essential components, a thermosetting resin component A and a high-molecular component B which are evenly compatible and miscible with each other at a temperature of 5 to 40° C. without being separated from each other, and a curing agent component C,

the composition having a nature that separation is made into the following in the adhesive composition after the adhesive composition comes into contact with an adherend and after the thermosetting resin component A is cured:

particulate structures a1 which are higher in the concentration of the thermosetting resin component A than the surrounding of the particulate structures a 1, and have an average diameter D1;

particulate structures a2 which are present in the particulate structures a1, have an average diameter D2 smaller than the average diameter D1, and are higher in the concentration of the thermosetting resin component A than the particulate structures a1;

a region b3 which is present in the particulate structures a1, is higher in the concentration of the high-molecular component B than the particulate structures a1, and is different region from the particulate structures a2;

a region b2 which is higher in the concentration of the high-molecular component 13 than the particulate structures a1; and

particulate structures a4 which have an average diameter D6 smaller than the average diameter D1, and are higher in the concentration of the thermosetting resin component A than the region b2.

(8) The adhesive composition according to item (7), wherein the average diameter D1 and/or the average diameter D6 is/are 1 to 30% of the average diameter D1.

(9) The adhesive composition according to item (7) or (8), wherein the average diameter D2 and/or the average diameter D6 is/are 2 to 200 nm.

(10) An adhesive composition comprising, as essential components, a thermosetting resin component A and a high-molecular component B which are evenly compatible and miscible with each other at a temperature of 5 to 40° C. without being separated from each other, and a curing agent component C,

the composition having a nature that separation is made into the following in the adhesive composition after the adhesive composition comes into contact with an adherend and after the thermosetting resin component A is cured:

particulate structures a1 which are higher in the concentration of the thermosetting resin component A than the surrounding of the particulate structures a1, and have an average diameter D1;

a region b2 which is higher in the concentration of the high-molecular component B than the particulate structures a1; and

particle-continued structures and/or co-continuous-phase structures a3 which are higher in the concentration of the thermosetting resin component A than the region b2, and have an average diameter D3 smaller than the average diameter D1 of the particulate structures a1.

(11) The adhesive composition according to item (10), wherein when the distance between the particulate structures a1 and the particle-continued structures and/or co-continuous-phase structures a3 is represented by the distance D4, the distance D4 is 10 to 90% of the average diameter D1.

(12) The adhesive composition according to item (10) or (11), wherein when the width between the particulate structures a1 and the particle-continued structures and/or co-continuous-phase structures a3 is represented by the width D5, the width D5 is 10 to 200% of the average diameter D1.

(13) The adhesive composition according to any one of items (1) to (12), wherein the average diameter D1 of the particulate structures is 200 nm or more.

(14) The adhesive composition according to any one of items (1) to (13), wherein the curing agent component C comprises a compound having an amino group.

(15) The adhesive composition according to any one of items (1) to (14), wherein the curing agent component C comprises an aromatic amine compound.

(16) The adhesive composition according to any one of items (1) to (15), wherein the thermosetting resin component A is an epoxy resin having two or more epoxy groups.

(17) The adhesive composition according to item (16), wherein the epoxy resin having two or more epoxy groups has a weight-average molecular weight less than 3,000.

(18) The adhesive composition according to item (16), wherein the epoxy resin having two or more epoxy groups has a weight-average molecular weight less than 1,500.

(19) The adhesive composition according to any one of items (16) to (18), wherein the epoxy resin having two or more epoxy groups has polarity.

(20) The adhesive composition according to any one of items (16) to (19), wherein the epoxy resin having two or more epoxy groups is a bisphenol A type epoxy resin.

(21) The adhesive composition according to any one of items (1) to (20), wherein the high-molecular component B is an acrylic copolymer having a weight-average molecular weight of 100,000 or more.

(22) The adhesive composition according to item (21), wherein the high-molecular component B is an epoxy-group-containing acrylic copolymer containing, as a copolymerization component, glycidyl acrylate or glycidyl methacrylate in a proportion of 0.5 to 10% by mass, and having a glass transition temperature of −10° C. or higher.

(23) The adhesive composition according to any one of items (1) to (22), wherein the high-molecular component B is contained in an amount of 100 to 900 parts by mass relative to 100 parts by mass of the thermosetting resin component A.

(24) The adhesive composition according to any one of items (1) to (23), wherein the following are incorporated into a solvent: the thermosetting resin component A; the high-molecular component B, the amount of which is 100 to 900 parts by mass relative to 100 parts by mass of the thermosetting resin component A; and the curing agent component C, the amount of which is 0.5 to 2 times the chemical equivalent of the thermosetting resin component A.

(25) A bonding member containing an adhesive layer obtained by forming an adhesive composition as recited in any one of items (1) to (23) into a film form.

(26) A process for producing a bonding member, comprising the steps of: painting an adhesive composition as recited in any one of items (1) to (23) onto a film as an adherend;

heating and drying the resultant to form a painted film of the adhesive composition; and

covering the painted film of the adhesive composition with another film.

(27) A support member for semiconductor mounting, comprising a bonding member as recited in item (25) over a semiconductor element mounted surface of a support member.

(28) A process for producing a support member for semiconductor mounting, wherein a bonding member as recited in item (25) is adhered onto a semiconductor element mounted surface of a support member.

(29) A semiconductor device, wherein a bonding member as recited in item (25) is used to bond a semiconductor element and a support member to each other.

(30) A semiconductor device, wherein a support member for semiconductor mounting as recited in item (27) is used.

(31) A process for producing a semiconductor device, comprising the steps of bonding a semiconductor element and a support member to each other or bond a semiconductor element and a support member for semiconductor mounting as recited in item (27) to each other by using a bonding member as recited in item (25); and

connecting electrodes of the semiconductor element and a wiring board which becomes the support member to each other by wire bonding or inner lead bonding of tape automated bonding.

### BRIEF DESCRIPTION OF THE DRAWINGS

FIG. 1 is a conceptual view of a cross section of an adhesive composition cured product which is orthogonal to an adherend, the product being obtained by bringing an adhesive composition into contact with the adherend, and then causing a thermosetting resin component therein to curing reaction.

FIG. 2 is a conceptual view of the cross section of the adhesive composition cured product, which is orthogonal to the adherend, the product being obtained by bringing the adhesive composition into contact with the adherend, and then causing the thermosetting resin component to the curing reaction.

FIG. 3 is a conceptual view of a cross section of an adhesive composition cured product which is orthogonal to an adherend, the product being obtained by bringing an adhesive composition in the following case into contact with the adherend, and then causing a thermosetting resin component A therein to curing reaction: a case where structures separated into the form of particles wherein the concentration of the thermosetting resin component A is high are put onto each other into two or more layers near a surface of the composition which contacts the adherend.

FIG. 4 is a conceptual view of the orthogonal cross section after the adherend in FIG. 1 is peeled.

FIG. 5 is a conceptual view of the orthogonal cross section after the adherend in FIG. 1 is peeled.

FIG. 6 is a conceptual view of the orthogonal cross section after the adherend in FIG. 1 is peeled.

FIG. 7 is a conceptual view of a phase structure wherein the thermosetting resin component A is separated into particulate structures a1 (2) wherein the concentration of the thermosetting resin component A is larger than that in the surrounding, and a region b1 (5a) wherein the concentration of a high-molecular component B is larger.

FIG. 8 is a conceptual view of particulate structures a2 (3a) and particulate structures a4 (4a), which are separated into smaller sizes than those of the particulate structures a1 (3).

FIG. 9 is a conceptual view of a structure separated into particle (4c)—continued structures and/or co-continuous-phase structures a3 (11), the particle (4c) having an average diameter D3 smaller than the average diameter D1 of the particulate structures a1, so as to surround the particulate structures a1 (3).

FIG. 10 is a conceptual view of the phase structure of an embodiment of the adhesive composition of the invention after the composition is cured.

FIG. 11 is a field emission type transmission electron microscopic image of a cross section of an adherend-adhered sample bonding member I obtained in Example 1.

FIG. 12 is a field emission type transmission electron microscopic image of a cross section of an adherend-adhered sample bonding member II obtained in Example 2.

FIG. 13 is a field emission type transmission electron microscopic image of a cross section of an adherend-adhered sample bonding member III obtained in Example 3.

FIG. 14 is a field emission type transmission electron microscopic image of a cross section of a bonding member VIII obtained in Example 4.

FIG. 15 is a field emission type transmission electron microscopic image of a cross section of an adherend-adhered sample bonding member VI obtained in Comparative Example 3.

FIG. 16 is a field emission type transmission electron microscopic image of a cross section, after peeling-evaluation, of the adherend-adhered sample bonding member I obtained in Example 1.

FIG. 17 is a field emission type transmission electron microscopic image of a cross section of the adherend-adhered sample bonding member I obtained in Example 1.

FIG. 18 is a field emission type transmission electron microscopic image of a cross section of the adherend-adhered sample bonding member II obtained in Example 2.

FIG. 19 is a field emission type transmission electron microscopic image of a cross section of the adherend-adhered sample bonding member III obtained in Example 3.

FIG. 20 is a field emission type transmission electron microscopic image of a cross section of the adherend-adhered sample bonding member VI obtained in Comparative Example 3.

FIG. 21 is a field emission type transmission electron microscopic image of a cross section of the adherend-adhered sample bonding member I obtained in Example 1.

FIG. 22 is an image obtained by inverting white and black in FIG. 21 to each other.

FIG. 23 is an image obtained by making FIG. 22 three-dimensional.

FIG. 24 is a field emission type transmission electron microscopic image of a cross section of the adherend-adhered sample bonding member II obtained in Example 2.

FIG. 25 is a field emission type transmission electron microscopic image of a cross section of the adherend-adhered sample bonding member III obtained in Example 3.

### BEST MODES FOR CARRYING OUT THE INVENTION

Hereinafter, a detailed description will be made about best modes for carrying out an adhesive composition, a bonding member, a support member for semiconductor mounting and a semiconductor device of the invention, and a process for producing these.

First, individual components of the adhesive composition of the invention are described.

<Thermosetting Resin Component A>

A thermosetting resin component A used in the adhesive composition of the invention is a polymeric material having a nature that when the material is heated, three-dimensional bonds are formed between molecules thereof so that the material is cured. After the component A is cured, the component A exhibits adhesive effect. It is sufficient for a combination of the component A with a high-molecular component B used in the adhesive composition of the invention that the component A is evenly compatible and miscible with the component B at a temperature of 5 to 40° C. without being separated from each other, and further the thermosetting resin component A is cured, whereby the thermosetting resin component A is separated into the form of particles wherein the concentration of the thermosetting resin component A is higher than that in the surrounding. The component A is not particularly limited, and specific examples thereof include epoxy resin, phenol resin, melamine resin, urea resin, urethane resin, unsaturated polyester resin, alkyd resin, and silicone resin. These may be used alone or in combination of two or more thereof.

When acrylic copolymer is selected as the high-molecular component B, an epoxy resin having two or more epoxy groups is preferably used as the thermosetting resin component A in order to give a nature that the thermosetting resin component A is evenly compatible and miscible therewith at a temperature of 5 to 40° C. without being separated therefrom, and further the thermosetting resin component A is cured, whereby the thermosetting resin component A is separated into the form of particles wherein the concentration of the component A is higher than that in the surrounding. It is allowable to use the epoxy resin wherein the weight-average molecular weight is preferably less than 3,000, more preferably less than 1,500, even more preferably less than 1,000.

The epoxy resin having two or more epoxy resin groups is preferably a resin having polarity, more preferably a resin having a large polarity.

Examples of the epoxy resin having two epoxy groups include bisphenol A type epoxy resin, bisphenol F type epoxy resin, diglycidyl ether of naphthalenediol, and other glycidyl ethers of various diol compounds. Of these compounds, bisphenol A type epoxy resin is more preferably used.

When the thermosetting resin component A is rendered an epoxy resin having a weight-average molecular weight in the above-mentioned range, two or more epoxy groups and polarity, particulate structures can easily be formed when the thermosetting resin component A is being cured. Moreover, an uncured portion of the epoxy resin is easily shifted to the region contacting an adherend.

As the above-mentioned epoxy resin, which is specifically an epoxy resin having a weight-average molecular weight less than 3,000 and a large polarity, available examples are as follows:

EPICOAT 807 (weight-average molecular weight: 340, and epoxy equivalent: 160-175 g/eq), EPICOAT 827 (weight-average molecular weight: 370, and epoxy equivalent: 180-190 g/eq), and EPICOAT 828 (weight-average molecular weight: 380, and epoxy equivalent: 184-194 g/eq), manufactured by Yuka-Shell Epoxy Co., Ltd.; D.E.R. 330 (weight-average molecular weight: 360, and epoxy equivalent: 176-185 g/eq), D.E.R. 331 (weight-average molecular weight: 375, and epoxy equivalent: 182-192 g/eq), and D.E.R. 362 (weight-average molecular weight: 390, and epoxy equivalent: 185-205 g/eq), manufactured by Dow Chemical Japan Ltd.; YD8125 (weight-average molecular weight: 340, and epoxy equivalent: 173 g/eq), and YDF8170 (weight-average molecular weight: 320, and epoxy equivalent: 159 g/eq), manufactured by Tohto Kasei Co., Ltd.; and other bisphenol A type or bisphenol F type liquid resins.

As epoxy resin, a polyfunctional epoxy resin may be added to make the glass transition temperature high. Examples of the polyfunctional epoxy resin include phenol Novolak type epoxy resin, and cresol Novolak type epoxy resin. These polyfunctional epoxy resins preferably have a weight-average molecular weight within the range of 1,000 to 3,000.

An available example of phenol Novolak type epoxy resin is EPPN-201 (epoxy equivalent: 180-200 g/eq) manufactured by Nippon Kayaku Co., Ltd.

Available examples of cresol Novolak type epoxy resin include ESCN-190 (epoxy equivalent: 190-200 g/eq), and ESCN-195X (epoxy equivalent: 193-203 g/eq), manufactured by Sumitomo Chemical Co., Ltd.; EOCN1012, EOCN1025 (epoxy equivalent: 190-205 g/eq), and EOCN1027 (epoxy equivalent: 195-210 g/eq), manufactured by Nippon Kayaku Co., Ltd.; and YDCN701 (weight-average molecular weight: 1375, and epoxy equivalent: 200 g/eq), YDCN702 (weight-average molecular weight: 1543, and epoxy equivalent: 204 g/eq), YDCN703 (weight-average molecular weight: 1723, and epoxy equivalent: 209 g/eq), and YDCN704 (weight-average molecular weight: 2559, and epoxy equivalent: 206 g/eq), manufactured by Tohto Kasei Co., Ltd.

In the invention, any weight-average molecular weight is measured by gel permeation chromatography, and using a standard polystyrene calibration curve to make a conversion.

<High-Molecular Component B>

It is sufficient for the high-molecular component B used in the adhesive composition of the invention that the component B is evenly compatible and miscible with the thermosetting resin component A at a temperature of 5 to 40° C. without being separated from each other, and further a combination thereof with the thermosetting resin component A permits the following: when the thermosetting resin component A is cured, whereby the thermosetting resin component A is separated into the form of particles wherein the concentration of the component A is higher than that in the surrounding. The high-molecular component B is not particularly limited, specific examples thereof include thermosetting plastics, crosslinking reaction rubbers, thermoplastic elastomers, phenoxy resin, and high-molecular epoxy resin. These may be used alone or in combination of two or more thereof.

Of these examples, an acrylic copolymer having a weight-average molecular weight of 100,000 or more is preferably used as the high-molecular component B. When an acrylic copolymer is used as the high-molecular component B, the thermosetting resin component A is preferably an epoxy resin having two or more epoxy groups, and is more preferably an epoxy resin having two or more epoxy groups, a weight-average molecular weight less than 3,000, and polarity, as described above.

If the weight-average molecular weight of the acrylic copolymer is less than 100,000, adhesive property and heat resistance necessary for the adhesive composition to be obtained may not be obtained. For this reason, the weight-average molecular weight is preferably from 200,000 to 3,000,000, more preferably from 300,000 to 1,000,000. If the weight-average molecular weight is less than 200,000, the strength or flexibility may be declined when the composition is in a sheet or film form, or the tackiness may be increased. If the molecular weight is more than 3,000,000, the flowability is small so that the fillability into wiring circuits may be declined.

The amount of glycidyl acrylate or glycidyl methacrylate, which is used as a copolymerizable monomer component of the acrylic copolymer, is preferably from 0.5 to 10% by mass of the acrylic copolymer, more preferably from 2 to 6% by mass of the acrylic copolymer. If the amount of glycidyl acrylate or glycidyl methacrylate, which is used as a copolymerizable monomer component of the acrylic copolymer, is less than 0.5% by mass, the adhesive force may be lowered. If the amount is more than 10% by mass, the composition may be gelatinized.

In the case of using, as a copolymerizable monomer component of the acrylic copolymer, acrylic acid, which is of a carboxylic acid type, or hydroxymethyl methacrylate, which is of a hydroxyl group type, the composition is easily gelatinized in a vanish state, so as to cause a problem that the adhesive force of the adhesive composition is lowered by a rise in the cure extend thereof in a B stage state, and other problems. Thus, the case is unfavorable.

Examples of a different copolymerizable monomer component of the acrylic copolymer include ethyl (meth)acrylate, butyl (meth)acrylate, acrylonitrile, and styrene, which may be used alone or in combination of two or more thereof. The blend ratio therebetween is decided, considering the glass transition temperature of the acrylic copolymer. The glass transition temperature is in particular preferably −10° C. or higher since the adhesive property and the heat resistance are high. If the glass transition temperature is lower than −10° C., in the use of the adhesive composition of the invention formed into a film form as an adhesive layer, the tackiness of the adhesive layer may become large in a B stage state so that the handleability may be deteriorated.

The polymerization method for the acrylic copolymer is not particularly limited, and may be pearl polymerization, solution polymerization, or the like.

It is more preferred that the high-molecular component B is an epoxy-group-containing acrylic copolymer containing 0.5 to 10% by mass of glycidyl acrylate or glycidyl methacrylate as a copolymerizable monomer component and having a glass transition temperature of −10° C. or higher for the following reason: in the case of using, as the thermosetting resin component A, an epoxy resin having two or more epoxy groups, the component A and the component B are evenly compatible and miscible with each other at a temperature of 5 to 40° C. without being separated from each other; and when the thermosetting resin component A is cured, the thermosetting resin component A is easily separated into particulate structures. The epoxy-group-containing acrylic copolymer containing 0.5 to 10% by mass of glycidyl acrylate or glycidyl methacrylate as a copolymerizable monomer component and having a glass transition temperature of −10° C. or higher is not particularly limited. An available example thereof is HTR-860P-3 (trade name) manufactured by Nagase ChemteX Corp. (weight-average molecular weight: 800,000, and glass transition temperature: −7 to 12° C.).

The blend ratio between the thermosetting resin component A and the high-molecular component B used in the adhesive composition of the invention is not particularly limited as far as the component A and the component B are evenly compatible and miscible with each other at a temperature of 5 to 40° C. without being separated from each other, and the thermosetting resin component A is cured, whereby the thermosetting resin component A is easily separated into particulate structures wherein the concentration of the component A is higher than that in the surrounding. The amount of the high-molecular component B is preferably from 100 to 900 parts by mass, more preferably from 150 to 400 parts by mass. If the amount of the high-molecular component B is less than 100 parts by mass relative to 100 parts by mass of the thermosetting resin component A, the component B tends to be easily separated from the thermosetting resin component A at a temperature of 5 to 40° C. so that no compatibility is obtained therebetween. Additionally, the elasticity tends to be decreased, and the effect of restraining the flowability tends to be small when the composition is formed. If the amount is more than 900 parts by mass, the handleability tends to be declined at high temperature.

<Curing Agent Component C>

A curing agent component C is used to advance easily curing reaction of the thermosetting resin component A used in the adhesive composition of the invention by heat or rays such as ultraviolet rays, an electron beam, or the like.

When an epoxy resin having two or more epoxy groups is used as the thermosetting resin component A, the curing agent component C in the invention may be a compound used ordinarily as a curing agent component for epoxy resin. Examples thereof include amine, polyamide, acid anhydride, polysulfide, boron trifluoride, and compounds each having in a single molecule thereof two or more phenolic hydroxyl groups, such as bisphenol A, bisphenol F, bisphenol S, phenol Novolak resin, bisphenol Novolak resin, and other curing agents having polarity.

Of these examples, amine is preferred since by use of amine, which is any compound having an amino group, as the curing agent component C, the composition appears to be easily attracted to a material which is to be an adherend. According to the use, after the adhesive composition is brought into contact with an adherend and after the thermosetting resin component A is cured, particulate structures are formed in a larger amount near a surface of the composition which contacts the adherend than inside the adhesive composition. The use of amine, which is any compound having an amino group, as the curing agent component C is preferred also since the compound easily undergoes spinodal decomposition. Examples of amine, which has an amino group, include aliphatic amines, and aromatic amines.

Since any amino group shows a nature as an electron donating group when the group is substituted on an aromatic ring, the use of an aromatic amine as the curing agent component C is more preferred since the amine is easily attracted to a material which is to be an adherend and the curing rate is small, so as to result in the following: when the adhesive composition is brought into contact with the adherend, a period when the aromatic amine can be shifted to the region contacting the adherend is made long so that a large amount of the amine can be shifted; and when the thermosetting resin component A is cured, particulate structures are formed in a larger amount near the composition surface contacting the adherend.

In order for the curing agent component C to give a good curing performance, the use amount of the curing agent is preferably an amount permitting the agent to contain function groups in an amount 0.5 to 2 times the chemical equivalent of the thermosetting resin component A, more preferably an amount permitting the agent to contain function groups in an amount 0.8 to 1.2 times the chemical equivalent thereof. Together with the curing agent component C used in the adhesive composition of the invention, a curing promoter may be used since a period for thermal treatment for the curing can be shortened.

The curing promoter may be selected from various imidazoles, such as 2-methylimidazole, 2-ethyl-4-methylimidazole, 1-cyanoethyl-2-phenylimidazole, and 1-cyanoethyl-2-phenylimidazolium trimellitate; and other bases. About the imidazoles, products commercially available from Shikoku Chemicals Corp. may be used, which each have a trade name of 2E4MZ, 2PZ-CN or 2PZ-CNS.

When the adhesive composition of the invention is made into a bonding member, the use of a latent curing promoter is also preferred to make a term when the bonding member is usable long. Typical examples thereof include dicyandiamide, dihydrazide compounds such as adipic acid dihydrazide, guanamic acid, melamic acid, any adduct made from an epoxy compound and a dialkylamine, any adduct made from an amine and thiourea, and any adduct made from an amine and an isocyanate.

It is also effective to microencapsulate the curing agent component C, or the curing promoter.

The blend amount of the curing agent component is preferably from 0.1 to 20 parts by mass, more preferably from 0.5 to 15 parts by mass, even more preferably from 0.5 to 5 parts by mass relative to 100 parts by mass of the total of the thermosetting resin component A and the curing agent component C. If the amount is less than 0.1 parts by mass, the curing rate tends to become small. If the amount is more than 20 parts by mass, the usable period tends to become short.

<Other Components of the Adhesive Composition>

Fillers, such as an inorganic filler and an organic fillers, may be added alone or in combination to the adhesive composition of the invention to adjust various properties thereof. In order to improve the heat resistance or thermal conductivity, to adjust the melt viscosity, or to give thixotropy, an inorganic filler is preferred.

The inorganic filler is not particularly limited, and examples thereof include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, crystalline silica, and amorphous silica. These may be used alone or in combination of two or more thereof. In order to improve the thermal conductivity, preferred is aluminum oxide, aluminum nitride, boron nitride, crystalline silica, amorphous silica or the like.

To adjust the melt viscosity or to give thixotropy, preferred is aluminum hydroxide, magnesium hydroxide, calcium carbonate, magnesium carbonate, calcium silicate, magnesium silicate, calcium oxide, magnesium oxide, aluminum oxide, crystalline silica, amorphous silica, or the like.

The use amount of the inorganic filler is preferably from 1 to 20 parts by volume relative to 100 parts by volume of the adhesive composition. If the amount is less than 1 part by volume, the effect of the addition is insufficient. If the amount is more than 20 parts by volume, at the time of making the adhesive composition into an adhesive layer the following problems may be caused: a rise in the storage elasticity of the adhesive layer; a fall in the adhesive property thereof a fall in electrical characteristics thereof based on remaining voids; and others.

About the filler, the contact angle thereof with water is preferably 100 degrees or less. If the contact angle with water is more than 100 degrees, the effect of the filler tends to be decreased. When the contact angle with water is 60 degrees or less, in particular, an effect of an improvement in reflow resistance is favorably high.

The contact angle of the filler with water is obtained by subjecting the filler to compression molding to form a flat plate, dropping down water droplets thereon, and then measuring the angle at which the water droplets contact the flat plate with a contact angle meter.

The average particle diameter of the filler is preferably 0.005 μm or more and 0.1 μm or less.

If the average particle diameter is less than 0.005 μm, the dispersibility and the fluidity tend to be lowered. If the diameter is more than 0.1 μm, the effect of improving the adhesive property tends to be decreased.

Examples of the filler having a contact angle of 100 degrees or less with water and an average particle diameter of 0.005 μm or more and 0.1 μm or less include silica, alumina and antimony oxide. Specifically, the following can be given as examples of silica: NanoTek SiO₂ [trade name] (contact angle: 43 degrees, and average particle diameter: 0.012 μm)) manufactured by C. I. Kasei Co., Ltd.; and AEROSIL 50 [trade name] (contact angle: 95 degrees, and average particle diameter: 0.03 μm) manufactured by Nippon Aerosil Co., Ltd.

PATOX-U [trade name] (contact angle: 43 degrees, and average particle diameter: 0.02 μm) manufactured by Nihon Seiko Co., Ltd. is given as an example of antimony oxide (specifically, diantimony trioxide).

The addition amount of the filler is preferably 5 parts or more by mass and 50 parts or less by mass relative to 100 parts by mass of the total of the curing agent component C and the thermosetting resin component A. If the amount is less than 5 parts by mass, the effect of improving the humidity resistance tends not to be sufficiently obtained. If the amount is more than 50 parts by mass, a rise in the storage elasticity of the adhesive, a fall in the adhesive property, and other problems tend to be easily caused. The amount is in particular preferably 10 parts or more by mass and less than 30 parts by mass.

Various types of coupling agents may be added to the adhesive composition of the invention to make bonding between interfaces of the individual components or the wettability therebetween. The coupling agent may be of a silane type, titanium type or aluminum type, or of some other type. In order to make bonding between interfaces of the individual components or the wettability therebetween, a silane coupling agent is preferred.

The silane coupling agent is not particularly limited, and examples thereof include vinylsilanes such as vinyltrichlorosilane, vinyltris(β-methoxyethoxy)silane, vinyltriethoxysilane, and vinyltrimethoxysilane; methacryloylsilanes such as γ-methacryloxypropyltrimethoxysilane, γ-methacryloxypropylmethyldimethoxysilane, 3-methacryloxypropyl-trimethoxysilane, and methyltri(methacryloyloxyethoxy)silane; epoxy-group-containing silanes such as β-(3,4-epoxycyclohexyl)ethyltrimethoxysilane, γ-glycidoxypropyltrimethoxysilane, γ-glycidoxypropylmethyldimethoxysilane, γ-glycidoxypropylmethyldiethoxysilane, and methyltri(glycidyloxy)silane; aminosilanes such as N-β (aminoethyl) γ-aminopropyltrimethoxysilane, N-β (aminoethyl) γ-aminopropylmethyldimethoxysilane, γ-aminopropyltriethoxysilane, γ-ureidopropyltriethoxysilane, N-β-aminoethyl-γ-aminopropyltrimethoxysilane, N-phenyl-γ-aminopropyltrimethoxysilane, 3-aminopropylmethyldiethoxysilane, 3-aminopropyltrimethoxysilane, 3-aminopropyl-tris(2-methoxy-ethoxy-ethoxy)silane, N-methyl-3-aminopropyltrimethoxysilane, triaminopropyl-trimethoxysilane, 3-(4,5-dihydroimidazole-l-yl)-propyltrimethoxysilane, and amyltrichlorosilane; mercaptosilanes such as γ-mercaptopropyltrimethoxyislane, γ-mercaptopropyltriethoxysilane, 3-mercaptopropyl-methyldimethoxysilane; urea-bond-containing silanes such as 3-ureidopropyltriethoxysilane, and 3-ureidopropyltrimethoxysilane; isocyanate-group-containing silanes such as trimethylsilyl isocyanate, dimethylsilyl isocyanate, methylsilyl triisocyanate, vinylsilyl triisocyanate, phenylsilyl triisocyanate, tetraisocyanate silane, and ethoxysilane isocyanate; 3-chloropropyl-group-containing silanes such as 3-chloropropyl-methyldimethoxysilane, and 3-chloropropyl-dimethoxysilane; and 3-cyanopropyl-triethoxysilane, hexamethyldisilazane, N,N-bis(trimethylsilyl)acetoamide, methyltrimethoxysilane, methyltriethoxysilane, ethyltrichlorosilane, n-propyltrimethoxysilane, isobutyltrimethoxyislane, octyltriethoxysilane, phenyltrimethoxysilane, phenyltriethoxysilane, N-β (N-vinylbenzylaminoethyl)-γ-aminopropyltrimethoxysilane, octadecyldimethyl[3-(trimethoxysilyl)propyl]ammonium chloride, γ-chloropropylmethyldichlorosilane, γ-chloropropylmethyldimethoxysilane, and γ-chloropropylmethyldiethoxysilane. These may be used alone or in combination of two or more thereof.

About the silane coupling agents described above, the following are commercially available from Nippon Unicar Co., Ltd.: γ-glycidoxypropyltrimethoxysilane, the trade name which is NUC A-187; γ-mercaptopropyltrimethoxysilane, that of which is NUC A-189; γ-aminopropyltriethoxysilane, that of which is NUC A-1100; γ-ureidopropyltriethoxysialne, that of which is NUC A-1160; and N-β-aminoethyl-γ-aminopropyltrimethoxysilane, that of which is NUC A-1120.

The titanium coupling agent is not particularly limited, and examples thereof include isopropyltrioctanoyl titanate, isopropyldimethacrylisostearoyl titanate, isopropyltridodecylbenzenesulfonyl titanate, isopropylisostearoyldiacryl titanate, isopropyltri(dioctylphosphate) titanate, isopropyltricumylphenyl titanate, isopropyltris(dioctylpyrophosphate) titanate, isopropyltris(n-aminoethyl) titanate, tetraisopropylbis(dioctylphosphate) titanate, tetraoctylbis(ditridecylphosphate) titanate, tetra(2,2-diallyloxymethyl-1-butyl)bis(ditridecyl)phosphate titanate, dicumylphenyloxyacetate titanate, bis(dioctylpyrophosphate)oxyacetate titanate, tetraisopropyl titanate, tetra-n-butyl titanate, butyl titanate dimer, tetra(2-ethylhexyl)titanate, titaniumacetyl acetonate, polytitaniumethyl acetonate, titaniumoctylene glycolate, an ammonium salt of titanium lactate, titanium lactate, titanium lactate ethyl ester, titaniumtriethanol aminate, polyhydroxy titanium stearate, tetramethyl orthotitanate, tetraethyl orthotitanate, tetrapropyl orthotitanate, tetraisobutyl orthotitanate, stearyl titanate, cresyl titanate monomer, cresyl titanate polymer, diisopropoxy-bis(2,4-pentadionate)titanium (IV), diisopopyl-bis-triethanolamino titanate, octylene glycol titanate, tetra-n-butoxytitanium polymer, tri-n-butoxytitanium monostearate polymer, and tri-n-butoxytitanium monostearate. These may be used alone or in combination of two or more thereof.

The aluminum coupling agent is not particularly limited, and examples thereof include aluminum chelate compounds such as ethylacetoacetatealuminum diisopropylate, aluminum tris(ethylacetoacetate), alkylacetoacetatealuminum diisopropylate, aluminum monoacetylacetate bis(ethylacetoacetate), aluminum tris(acetylacetonate), aluminum monoisopropoxymonooleoxyethylacetoacetate, aluminum-di-n-botoxide-mono-ethylacetoacetate, and aluminum-di-isopropoxide-mono-ethylacetoacetate; and aluminum alkolates such as aluminum isopropylate, mono-sec-butoxyaluminum diisopropylate, aluminum-sec-butylate, and aluminum ethylate. These may be used alone or in combination of two or more thereof.

The addition amount of the coupling agent is preferably from 0.1 to 10 parts by mass relative to 100 parts by mass of the adhesive composition of the invention from the viewpoint of balance between the advantageous effects thereof and the heat resistance.

An ion capturing agent may be added to the adhesive composition of the invention to make the electric insulation reliability good by the adsorption or adhesion of ionic impurities when the composition absorbs humidity. The ion capturing agent is not particularly limited, and examples thereof include compounds each known as a copper-harm preventive for preventing copper from being ionized and eluted out, such as triazinethiol compounds and bisphenol reducing agents, and inorganic ion adsorbents such as zirconium compounds, antimony bismuth compounds, and magnesium aluminum compounds. These may be used alone or in combination of two or more thereof

The addition amount of the ion capturing agent is preferably from 1 to 10 parts by mass relative to 100 parts by mass of the adhesive composition of the invention from the viewpoint of balance between the advantageous effects thereof and the heat resistance.

<Adhesive Composition of the Invention>

The adhesive composition of the invention is an adhesive composition including, as essential components, a thermosetting resin component A and a high-molecular component B which are evenly compatible and miscible with each other at a temperature of 5 to 40° C. without being separated from each other, and a curing agent component C, and has any feature of adhesive compositions (A) to (D) or has two or more features thereof combined with each other, as described below.

(Adhesive Composition (A))

An embodiment of the adhesive composition of the invention is characterized in that after the adhesive composition comes into contact with an adherend and after the thermosetting resin component A is cured, the thermosetting resin component A is separated, in the adhesive composition, into particulate structures wherein the concentration of the thermosetting resin component A is larger than that in the surrounding of the particulate structures, and further the particulate structures are formed in a larger amount near a surface of the composition which contacts the adherend than inside the adhesive composition.

When the adhesive composition is used as, for example, a bonding member containing an adhesive layer obtained by forming the adhesive composition into a film form, the same or a different solid that is an object to be bonded through the adhesive layer is the “adherend”. However, when the phase separation structure of the adhesive composition of the invention, which can be indexes of the heat resistance, the crack resistance, the adhesive property and the exudation resistance of the composition, is evaluated, the adherend is rendered a polyimide film, specifically, a film (trade name: UPILEX 50-S) manufactured by Ube Industries, Ltd. Hereinafter, about the adhesive compositions (B) to (D) also, the definition of any “adherend” is the same.

For the adherend in a case where the adhesive composition of the invention is used as an adhesive layer of a bonding member, the following may be used: an organic compound such as a resist material for semiconductor; a metal such as gold, silver or copper; an inorganic material such as glass or a silicon wafer; or the like.

In order that the thermosetting resin component A is cured, thereby forming the particulate structures, wherein the concentration of the thermosetting resin component A is higher than that in the surrounding, in a larger amount near a surface of the composition which contacts the adherend than inside the adhesive composition, it would be necessary that after the adhesive composition, wherein the components are evenly compatible and miscible with each other without being separated from each other at or near room temperature (5 to 40° C.), comes into contact with the adherend and before the thermosetting resin component A undergoes curing reaction, the thermosetting resin component A and/or the curing agent component C is/are higher in concentration in regions near the composition surface contacting the adherend than in regions apart from the composition surface contacting the adherend.

It is important therefor that: after the adhesive composition, which comprises as essential components the thermosetting resin component A and the high-molecular component B evenly compatible and miscible with each other without being separated from each other at a temperature of 5 to 40° C., and the curing agent component C, comes into the adherend, the thermosetting resin component A and the curing agent component C are easily attracted to the adherend; when the thermosetting resin component A is being cured, the particulate structures are formed; and further when the thermosetting resin component A is not yet cured and/or is being cured, the component A is cured at a rate permitting to give a period when the component A is shifted to the vicinity of the adherend. This can be attained by using the above-mentioned individual components of the adhesive composition.

In the case of using, for example, a combination of polyimide as the adherend, epoxy resin as the thermosetting resin component A, and an aromatic amine, which has an amino group, as the hardener component C, the following is presumed: by effect of a matter that the electron withdrawing performance of carbonyl groups of polyimide attracts the aromatic amine, which has the electron donating amine group, in the hardener component C, a matter that the polarity of polyimide attracts hydrogen of the epoxy groups, and other matters, the concentrations of the epoxy resin and the aromatic amine, which has the amino group, are made high near the interfaces thereof with polyimide, so that a first-stage spinodal decomposition, which is started to the accompaniment of the curing of the epoxy resin, is caused, whereby the particulate structures higher in the concentration of the epoxy resin than the surrounding are formed in a larger amount near the composition surface contacting the adherend than inside the adhesive composition.

When the thermosetting resin component A is cured in the adhesive composition (A), such a mechanism for forming the phase separation structure causes the particulate structures, wherein the concentration of the thermosetting resin component A is higher than that in the surrounding, to be formed more largely near the surface contacting the adherend than inside the composition.

From the above, it is understood that in order to form the above-mentioned structure, important are not only the individual starting material components of the adhesive composition and the use amounts thereof but also the material of the adherend since the structure is easily obtained by use of an object having polarity and electron withdrawing performance as the adherend. Accordingly, when the adhesive composition (A) of the invention is used as a bonding member containing an adhesive layer obtained by forming the composition (A) into a film form, it is preferred that the material of the adherend is a material having polarity or electron withdrawing property since the material derives adhesive force so that a larger effect can be produced.

However, when the phase separation structure of the adhesive composition of the invention, which can be indexes of the heat resistance, the crack resistance, the adhesive property and the exudation resistance of the composition, is evaluated, a polyimide film, specifically, a film (trade name: UPILEX 50-S) manufactured by Ube Industries, Ltd. is used as the adherend. By limiting the adherend in evaluations of any adhesive composition, results which do not depend on the adherend can be obtained. Other conditions (curing conditions and the like) for check will be described later.

The phase structure formed by the adhesive composition of the invention will be described.

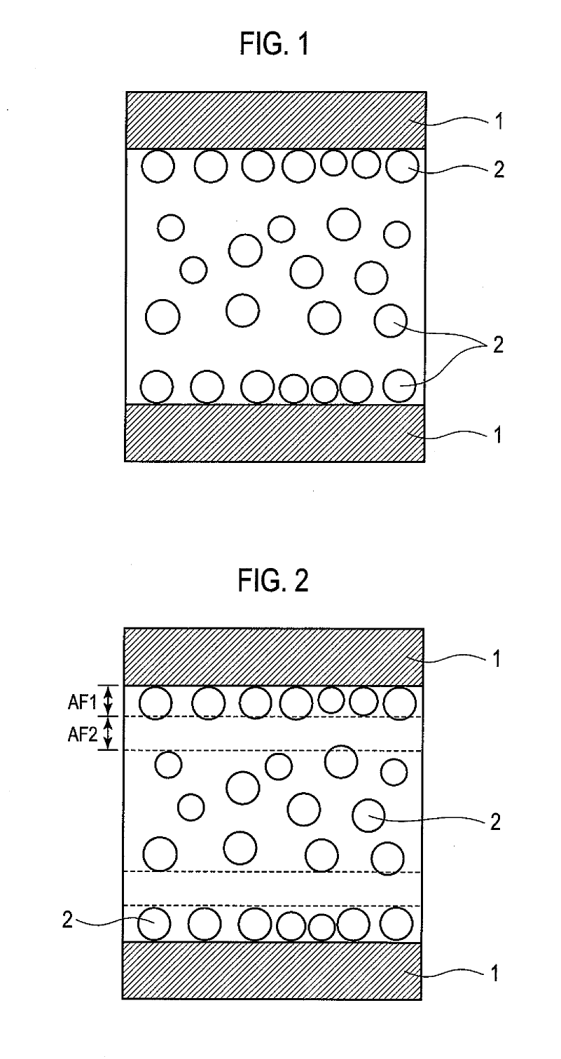

As illustrated in FIG. 1, the adhesive composition of the invention is characterized in that the thermosetting resin component A undergoes curing reaction, whereby the thermosetting resin component A is separated into particulate structures 2 wherein the concentration of the component A is larger than that in the surrounding, and further the particulate structures 2 are formed in a larger amount near a surface of the composition which contacts an adherend 1 than inside the composition.

This structure is formed by a first-stage spinodal decomposition after the composition is brought into contact with the adherend. About the mechanism for the formation, further researches will be required. As described above, in order to form this phase separation structure, it appears to be necessary that before the curing reaction, the thermosetting resin component A and/or the curing agent component C is/are higher in concentration in regions near the composition surface contacting the adherend than in regions apart from the composition surface contacting the adherend.

As described above, the inventors presume that, for example, in the case of using, as the thermosetting resin component A, an epoxy resin having a weight-average molecular weight less than 3,000 and/or using, as the hardener component, a compound having polarity, such as an aromatic amine, which has an amino group, the concentration of the component(s) is favorably made high in the regions near the composition surface contacting the adherend by the polarity or the electron withdrawing performance of the adherend, or some other effect.

As illustrated in FIG. 2, the area fraction of the particulate structures 2 to regions other than the structures 2 in an adhesive composition (A) section which is orthogonal to the adherend 1 after the curing is represented by AF, the average diameter of the particulate structures is represented by D1, the area fraction of a region having distances of 0 to D1 from the composition surface contacting the adherend to the other regions is represented by AF1, and the area fraction of a region having distances of D1 to D1×2 from the composition surface contacting the adherend to the other regions is represented by AF2. In this case, it is preferred that the adhesive composition has a relationship of AFI/AF2>1.05. When the composition satisfies relationship of AF1/AF2>1.05, stress applied from the outside and stress based on thermal hysteresis can be more effectively absorbed or relaxed. Thus, when the adhesive composition is made into an adhesive layer, the composition can be used also for thin-film bonding wherein a layer thickness is 30 pin or less, and the composition can gain practical properties, such as excellent adhesive property, heat resistance, crack resistance, and exudation resistance, which is a property that the adhesive less exudes.

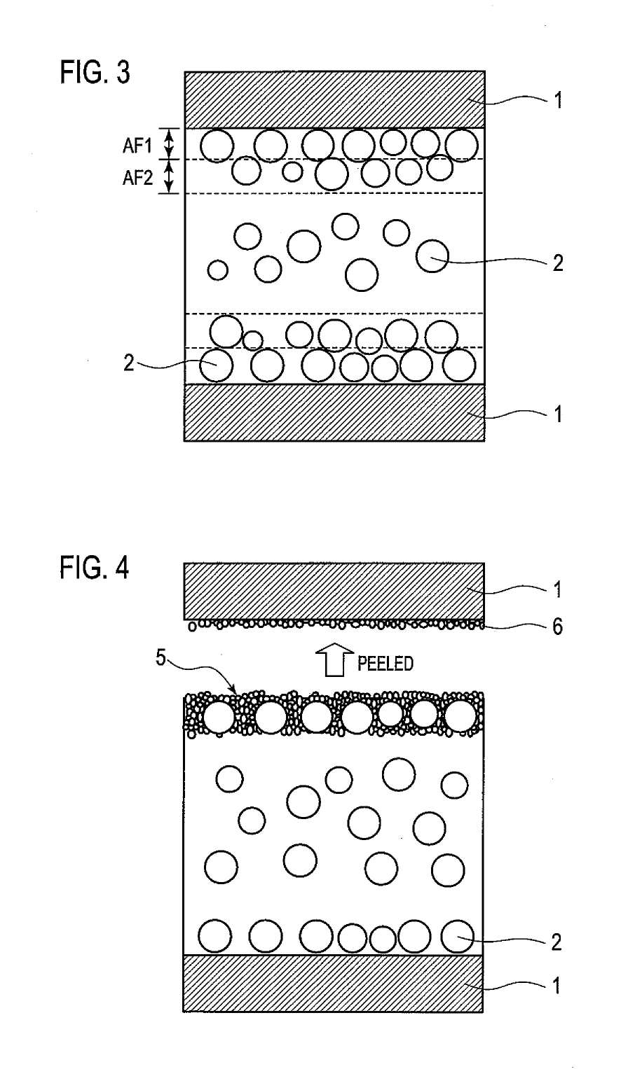

From this viewpoint, the relationship between AF1 and AF2 is preferably AF1/AF2>2, more preferably AF1/AF2>4. As illustrated in FIG. 3, in a case where the particulate structures 2 are put onto each other into the form of two or more layers near the composition surface contacting the adherend 1, the value of AF2 unfavorably becomes high even when the thermosetting resin component A undergoes curing reaction so that the particulate structures 2 are formed in a sufficiently larger amount near the composition surface contacting the adherend than inside the composition. Thus, when AF1/AF2>1.05 is satisfied, sufficient properties are obtained.

In order for the adhesive composition to satisfy the relationship of AF1/AF2>1.05, it is advisable to use the above-mentioned individual components. More specifically, the relationship can be prepared, for example, by using, as the thermosetting resin component A, an epoxy resin having a weight-average molecular weight less than 3,000, polarity and two or more epoxy groups, by using a hardener component C having polarity, or the like.

About the structure of the particulate structures in the cured composition, and uneven-distribution ratio of particulate structures such as the area fraction of the particulate structures relative to other regions, evaluation is made, for example, as follows: An adhesive composition of the invention is painted onto a polyimide film (specifically, a film (trade name: UPILEX 50-S) manufactured by Ube Industries, Ltd.) as an adherend, and then the thermosetting resin component A therein is caused to undergo curing reaction (conditions: drying at 60° C. for 30 minutes for removing the solvent, followed by heating and curing at 120° C. for 1 hour), so as to yield a sample bonding member. The sample bonding member is cut orthogonally to the adherend with a diamond knife to give a cut piece of 100 nm thickness. The vicinity of the interface between the adherend and the adhesive composition cured product in the resultant orthogonal cross section is photographed as an image having density difference with a field emission type transmission electron microscope. Data on this image are digitalized, and then the ratio of the area occupied by the particulate structures wherein the thermosetting resin component A concentration is higher in a given area is obtained.

A decision as to whether or not the particulate structures are formed in a larger amount in the composition surface contacting the adherend than inside the composition is specifically made on the basis of the following: whether or not the composition satisfies AF1/AF2>1.05, when the particulate structures constitute a single layer

In this case, an image wherein darkness and lightness are inverted to each other is obtained if the particulate structures partially drop down when the orthogonal cross section is cut out. It is therefore necessary to conduct an image-correcting treatment, or some other treatment in such areas.

The conformation of a matter that the concentration of the thermosetting resin component A is higher in the particulate structures than in the surrounding thereof can be attained by making a structure-observation of the orthogonal cross section obtained as described above with a scanning viscoelasticity microscope (production name: E-sweep manufactured by SII Nano Technology Inc., which may be referred to as “SVM” hereinafter). The SVM is a device equivalent to an atomic force microscope, and is a device capable of giving a difference in surface elasticity modulus (elasticity coefficient) as an image wherein a high-elasticity-modulus area is made bright and a low-elasticity-modulus area is made dark on the basis of a difference in the amplitude value of a response signal, in an observed region, to the amplitude value of a constant input signal. Specifically, in the case of using a combination of an aromatic epoxy resin as the thermosetting resin component A with an acrylic copolymer as the high-molecular component B, the particulate structures become bright in an SVM image of the orthogonal cross section. This demonstrates that the particulate structures are high in elasticity, that is, the composition of the combination is a composition rich in the thermosetting resin component A. The surrounding thereof is dark so as to be low in elasticity. According to this, it can be decided that the composition thereof is a composition rich in the high-molecular component B.

It is preferred that the average diameter D1 of the particulate structures is 200 nm or more in order that the adhesive composition can be used for thin-film bonding wherein a thickness is 30 μm or less, and the composition can gain practical properties, such as excellent adhesive property, heat resistance, crack resistance, and exudation resistance, which is a property that the adhesive less exudes. In a case where the average diameter D1 is set to 200 nm or more, for example, when the adherend is peeled in a region having distances of 0 to D1 from the composition surface contacting the adherend, this region is deformed or damaged so that stress therein can be relaxed. From this viewpoint, the average diameter D1 is more preferably 500 nm or more, more preferably 1 μm or more.

When the adhesive composition of the invention is made into a bonding member having an adhesive layer using the composition, for setting the average diameter D1 of the particulate structures to 200 nm or more, a method of making the thickness of the adhesive layer of the bonding member large, or making the curing temperature of the adhesive composition of the invention high, or some other method may be used. In connection with the adhesive composition itself, a method of using, as the curing agent component C, an aromatic amine or the like about which curing reaction advances slowly, or an aliphatic amine which easily undergoes phase separation, or using a combination thereof, or some other method may be used.

In order to set the average diameter D1 of the particulate structures to 200 nm or more, it is allowable that under consideration of the thermosetting resin component A and the high-molecular component B besides the above-mentioned curing agent component C, the adhesive composition is prepared, for example, as follows: a bisphenol A type epoxy resin is used as the thermosetting resin component A; an epoxy-group-containing acrylic copolymer which contains 0.5 to 10% by mass of glycidyl acrylate or glycidyl methacrylate as a copolymerizable component, having a weight-average molecular weight of 100,000 or more and having a glass transition temperature of −10° C. or higher is used as the high-molecular component B; an aromatic amine having an amino group, is used the curing agent component C; and the epoxy-group-containing acrylic copolymer is blended in an amount of 150 to 400 parts by mass relative to 100 parts by mass of the bisphenol A type epoxy resin, and the amino-group-having aromatic compound is blended in an amount 0.8 to 1.2 times the chemical equivalent of the bisphenol A type epoxy resin, whereby the preparation can easily be attained.

(Adhesive Composition (B))

Another embodiment of the adhesive composition of the invention is characterized in that after the adhesive composition comes into contact with an adherend and after the thermosetting resin component A is cured, the thermosetting resin component A is separated, in the adhesive composition, into particulate structures wherein the concentration of the thermosetting resin component A is larger than that in the surrounding of the particulate structures;

the particulate structures are formed in a larger amount near a surface of the composition which contacts the adherend than inside the adhesive composition;
and a region where the concentration of the high-molecular component B is higher, the region being around the particulate structures formed near the composition surface contacting the adherend, has a nature that when the adherend is peeled, pores are generated partially in the region by expansion stress, and/or the particulate structures formed near the composition surface contacting the adherend have a nature that when the adherend is peeled, the particulate structures partially undergo plastic deformation so as to be divided into fine fragments.

In the adhesive composition (B), the matter that the particulate structures are formed in a larger amount near the composition surface which contacts the adherend than inside the adhesive composition is the same as in the adhesive composition (A).

A nature which the adhesive composition (B) has will be described. The nature is a nature of improving the peel strength.

As illustrated in FIG. 4, in the adhesive composition of the invention, particulate structures 2 are formed in a larger amount near a surface of the composition which contacts an adherend 1 than inside the adhesive composition; and a region 5 of the high-molecular component B, this region being around the particulate structures 2 formed more largely near the composition surface contacting the adherend 1, has a nature that when the adherend 1 is peeled, pores are generated partially in the region 5 by expansion stress. To the peeled adherend 1 may adhere the pores 6 generated by the expansion stress.

The particulate structures generally involve a three-dimensional network structure, so as to be stronger than the high-molecular component B. By expansion stress when the adhered is peeled, pores are generated in the high-molecular component B around the particulate structures. It appears to the inventors that the generated pores form a sponge structure. Such a nature makes it possible to give an adhesive composition excellent in adhesive property. The shape and the size of the pores are not particularly limited. It is preferred that the shape is a largely extended shape and the size is about 10 to 300 nm.

Ideally, pores should be generated in the whole of the region of the high-molecular component B around the particulate structures by expansion stress; however, for gaining an excellent adhesive property, it is sufficient that the pores are generated partially in the region of the high-molecular component B since the expansion stress applied to this region appears to be very large at the time of the peeling.

When the adherend is peeled, it is sufficient for generating pores partially in the region of the high-molecular component B that the adhesive composition is prepared in the same way as the adhesive composition (A).

The method for checking whether or not pores are made partially in the region of the high-molecular component B of the adhesive composition (B), the shape thereof or the size thereof may be a checking method described below, using the same measuring sample as used in the confirmation of the particulate structures in the adhesive composition (A).

Specifically, an adhesive composition of the invention is painted onto an adherend (specifically, a polyimide film, specifically, a film (trade name: UPILEX 50-S) manufactured by Ube Industries, Ltd.,) and then the thermosetting resin component A therein is caused to undergo curing reaction (conditions: drying at 60° C. for 30 minutes for removing the solvent, followed by heating and curing at 120° C. for 1 hour), so as to yield a sample bonding member. The adhesive composition cured product of the sample bonding member is made into a test piece having a shape 10 cm×10 mm in size. The test piece is partially peeled at a speed of 0.50 mm/s to show a T-shaped look. The adhesive composition cured product, from which the adherend is peeled, is wrapped with normal-temperature curable epoxy wrapping resins (trade names: EPOFIX RESIN and EPOFIX HARDENER), and then the wrapped product is allowed to stand still at room temperature for 2 days, so as to be hardened. The resultant is cut orthogonally to the adherend with a diamond knife. This orthogonal cross section is photographed with a field emission type transmission electron microscope, and then the image is observed.

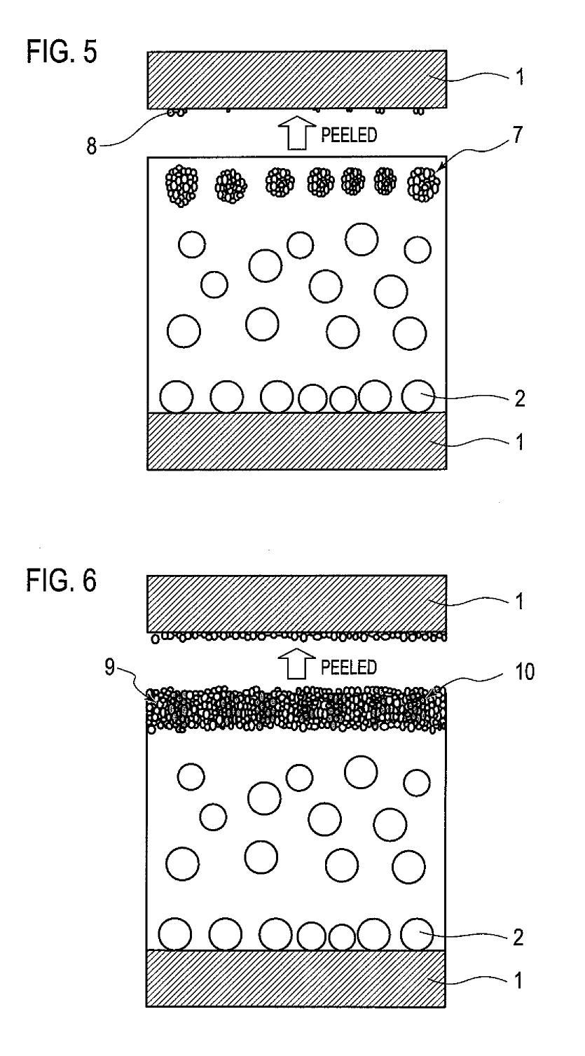

As illustrated in FIG. 5, in the case of particulate structures 7 which are small in the amount of three-dimensional linkage so as to be weak or fragile and are made of the thermosetting resin component A, in a case where a phase separation structure containing a large amount of a crosslinkage component is formed so as to be in a relatively strong state, or in some other case, at the time of peeling the adherend 1 the particulate structures 2 formed largely near the composition surface contacting the adherend 1 may partially undergo plastic deformation so as to be divided into fine fragments 7. In this case also, a large amount of peeling energy is consumed for the plastic deformation, so that the peel strength can be improved. To the peeled adherend 1 may adhere portions 8 of the particulate structures of the thermosetting resin component A divided into the fine fragments by the plastic deformation.

The method for checking whether or not the particulate structures undergo plastic deformation to be divided into fine fragments may be performed by taking a photograph with a field emission type transmission electron microscope and observing the resultant image in the same way for checking whether or not pores are generated partially in the region of the high-molecular component B of the adhesive composition (B).

For causing the particulate structures to undergo plastic deformation, so as to be divided into fine fragments when the adherend is peeled, it is sufficient that the adhesive composition is prepared in the same way as the adhesive composition (A).

The following are more preferred for the adhesive composition of the invention in order to consume expansion stress in the high-molecular component B and further consume a large amount of peeling energy for the plastic deformation of the particulate structures so that the adhesive composition obtains an excellent adhesive property: as illustrated in FIG. 6, particulate structures 2 are formed in a larger amount near the composition surface which contacts an adherend 1 than inside the adhesive composition; and further the composition has both of a nature that about a region of the high-molecular component B is higher, this region being around the particulate structures 2 formed largely near the composition surface contacting the adherend 1, pores 9 are generated partially in the region by expansion stress when the adherend 1 s peeled, and a nature that about the particulate structures 2 formed largely near the composition surface contacting the adherend, the particulate structures 2 partially undergo plastic deformation so as to be divided into fine fragments when the adherend 1 is peeled.

(Adhesive Composition (C))

Still another embodiment of the adhesive composition of the invention is characterized in that an adhesive composition having a nature that separation is made into the following in the adhesive composition after the adhesive composition comes into contact with an adherend and after the thermosetting resin component A is cured: particulate structures a1 which are higher in the concentration of the thermosetting resin component A than the surrounding of the particulate structures a1, and have an average diameter D1;

particulate structures a2 which are present in the particulate structures a1, have an average diameter D2 smaller than the average diameter D1, and are higher in the concentration of the thermosetting resin component A than the particulate structures a1;

a region b3 which is present in the particulate structures a1, is higher in the concentration of the high-molecular component B than the particulate structures a1, and is different region from the particulate structures a2;

a region b2 which is higher in the concentration of the high-molecular component B than the particulate structures a1; and

particulate structures a4 which have an average diameter D6 smaller than the average diameter D1, and are higher in the concentration of the thermosetting resin component A than the region b2.

Specifically, a first-stage spinodal decomposition is caused so that the high-molecular component B is separated into the region b1, wherein the concentration of the high-molecular component B is high, and the particulate structures a1, wherein the concentration of the thermosetting resin component A is high. Subsequently, inside the particulate structures a1, and in the region b1, wherein the concentration of the high-molecular component B is high, a second-stage spinodal decomposition is caused. The inside of the particulate structures a1 is separated into the particulate structures a2, which have the average diameter D2 smaller than the average diameter D1, and are higher in the concentration of the thermosetting resin component A than the particulate structures a1; and the region b3, which is present in the particulate structures a1, is higher in the concentration of the high-molecular component B than the particulate structures a1, and is different from the particulate structures a2. The region b1 appears to be further separated into the region b2, which is higher in the concentration of the high-molecular component B than the region b1 and the particulate structures a1; and the particulate structures a4, which have the average diameter D6 smaller than the average diameter D1, and are higher in the concentration of the thermosetting resin component A than the regions b1 and b2.

The matter that the composition has the above-mentioned structure after the composition is cured is an index for a matter that when the adhesive composition is used as an adhesive layer obtained by forming the composition into a film form, the layer is excellent in heat resistance, crack resistance, adhesive property and exudation resistance.

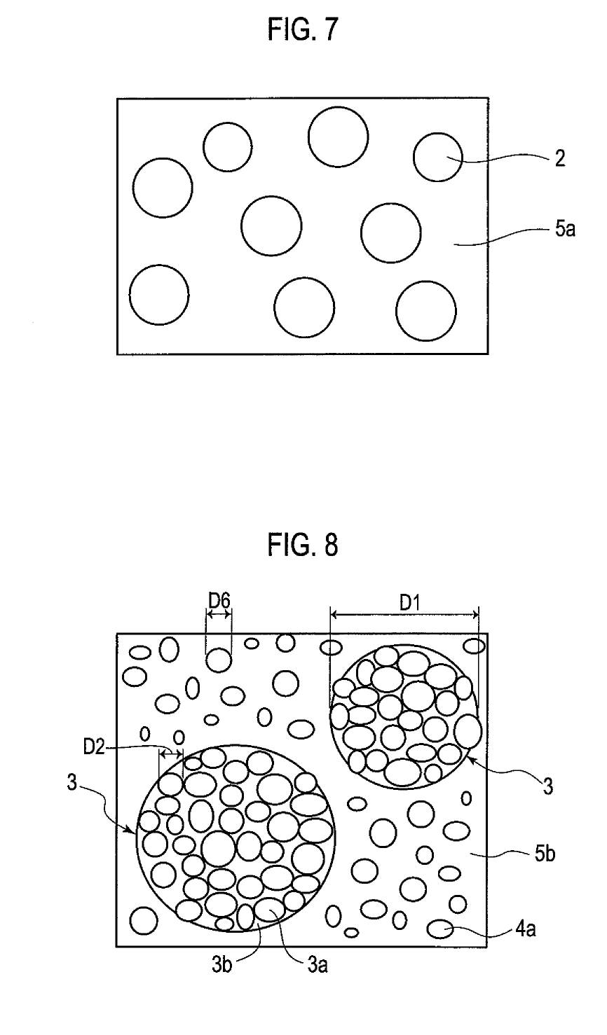

The structure based on this nature is a structure formed by the first-stage spinodal decomposition and the second-stage spinodal decomposition that are started to the accompaniment of the curing reaction of the thermosetting resin component A. About the mechanism for the formation, further researches will be required. In order to form this phase separation structure, as described above, by the first-stage spinodal decomposition based on the curing of the thermosetting resin component A, as illustrated in FIG. 7, the thermosetting resin component A and the high-molecular component B, which are evenly compatible and miscible with each other, are separated into the region b1 (reference number 5a in FIG. 7), wherein the concentration of the high-molecular component B is high, and the particulate structures a1 (reference number 2 in FIG. 7), wherein the concentration of the thermosetting resin component is high. As illustrated in FIG. 8, inside the separated particulate structures a1 (reference number 3 in FIG. 8), the second-stage spinodal decomposition is further caused, so that the inside is separated into the particulate structures a2 (reference number 3a in FIG. 8), which have the average diameter D2 smaller than the average diameter D1, and are higher in the concentration of the thermosetting resin component A than the particulate structures a1; and the region b3 (reference number 3b in FIG. 8), which is present in the particulate structures a1, is higher in the concentration of the high-molecular component B than the particulate structures a1, and is different from the particulate structures a2.

Moreover, in the region b1 also, the second-stage spinodal decomposition is caused, so that the region appears to be separated into the region b2 (reference number 5b in FIG. 8), which is higher in the concentration of the high-molecular component B than the region b1 and the particulate structures a1; and the particulate structures a4 (reference number 4a in FIG. 8), which have the average diameter D6 smaller than the average diameter D1 of the particulate structures a1, and are higher in the concentration of the thermosetting resin component A than the regions b1 and b2.

In order that at the time of making the adhesive composition into an adhesive layer in a film form, the composition can gain such an excellent adhesive property that the adhesive layer can be used even when the thickness thereof is 30 μm or less, and gain practical properties, such as heat resistance, crack resistance, and exudation resistance, which is a property that the adhesive less exudes, the average diameter D1 of the particulate structures a1 is preferably 200 nm or more

When the average diameter D1 is set to 200 nm or more, for example, the shape thereof is deformed or damaged in a case where the adherend is peeled, whereby peeling energy is relaxed so that the peel strength can be improved. For this viewpoint, the average diameter D1 is more preferably 500 nm or more, even more preferably 1 μm or more.

Similarly, when the adhesive composition is made into an adhesive layer in a film form, the average diameter D2 of the particulate structures a2 and/or the average diameter D6 of the particulate structures a4 is/are preferably from 2 to 200 nm, more preferably from 2 to 100 nm in order for the composition to gain such an excellent adhesive property that the composition can be used for thin-film bonding, wherein the thickness of the adhesive layer is 30 μm or less, and gain practical properties, such as heat resistance, crack resistance, and exudation resistance, which is a property that the adhesive less exudes.

In each of cases where the average diameter D2 and/or the average diameter D6 is/are less than 20 nm and are more than 100 nm, for example, the following improving function tends not to be sufficiently expressed: a function that when the adherend is peeled, the shape thereof is deformed or damaged, whereby peeling energy is relaxed so that the peel strength is improved.

For this reason, the average diameter D2 of the particulate structures a2 and/or the average diameter D6 of the particulate structures a4 is/are set preferably into the range of 1 to 30% of the average diameter D1 of the particulate structures a1, more preferably into that of 3 to 10%.

In order to construct the adhesive composition (c), it is advisable to use the above-mentioned individual components.

The method for setting the average diameter D2 of the particulate structures a2 and/or the average diameter D6 of the particulate structures a4 into the range of 2 to 200 nm, and the method for setting the diameter(s) D2 and/or D6 into the range of 1 to 30% of the average diameter D1 of the particulate structures a1 are not particularly limited. The settings are attained, for example, by setting the average diameter D1 of the particulate structures a1 to 200 nm or more.

Which of the average diameter D2 and the average diameter D6 is larger is undecided, and not particularly limited.

The method for measuring the average diameter D2 of the particulate structures a2 or the average diameter D6 of the particulate structures a4 may be performed in the similar way to the method for structure-confirmation of the particulate structures in the adhesive composition (A), or the like.

The existences of the particulate structures a1 and a2 and the regions b2 and b3 can be checked using a field emission type transmission electron microscope in the similar way to in the method for measuring the average diameter D1. The concentrations of the thermosetting resin component A and the high-molecular component B therein can also be checked using the SVM image of the adhesive composition (A).

(Adhesive Composition (D))

A different embodiment of the invention is an adhesive composition having a nature that separation is made into the following in the adhesive composition after the adhesive composition comes into contact with an adherend and after the thermosetting resin component A is cured:

particulate structures a1 which are higher in the concentration of the thermosetting resin component A than the surrounding of the particulate structures a1, and have an average diameter D1;

a region b2 which is higher in the concentration of the high-molecular component B than the particulate structures a1; and

particle-continued structures and/or co-continuous-phase structures a3 which are higher in the concentration of the thermosetting resin component A than the region b2, and have an average diameter D3 smaller than the average diameter D1 of the particulate structures a1.

Specifically, a first-stage spinodal decomposition is caused so that the high-molecular component B is separated into the region b1, wherein the concentration of the high-molecular component B is high, and the particulate structures a1, wherein the concentration of the thermosetting resin component A is high. Subsequently, inside the particulate structures a1, and in the region b1, wherein the concentration of the high-molecular component B is high, a second-stage spinodal decomposition is caused. The inside of the particulate structures a1 is separated into the particulate structures a2, which have the average diameter D2 smaller than the average diameter D1, and are higher in the concentration of the thermosetting resin component A than the particulate structures a1; and the region b3, which is present in the particulate structures a1, is higher in the concentration of the high-molecular component B than the particulate structures a1, and is different from the particulate structures a2. The region b1 is further separated into the region b2, which is higher in the concentration of the high-molecular component B than the region b1 and the particulate structures a1; and the particulate structures a4, which have the average diameter D6 smaller than the average diameter D1, and are higher in the concentration of the thermosetting resin component A than the regions b1 and b2.

Subsequently, it appears that a third-stage spinodal decomposition is caused, so that it is separated into the particle-continued structures and/or co-continuous-phase structures a3 so as to surround the particulate structures a1, wherein the structures a3 have the average diameter D3 smaller than the average diameter D1 of the particulate structures a1, and are higher in the concentration of the thermosetting resin component A than the region b2.

The matter that the composition has the above-mentioned structure after the composition is cured is an index for a matter that when the adhesive composition is used as an adhesive layer obtained by forming the composition into a film form, the layer is excellent in heat resistance, crack resistance, adhesive property and exudation resistance.

The structure based on this nature is a structure formed by the first-stage spinodal decomposition, the second-stage spinodal decomposition and the third-stage spinodal decomposition that are started to the accompaniment of the curing of the thermosetting resin component A. About the mechanism for the formation, further researches will be required. In order to form this phase separation structure, as described above, by the first-stage spinodal decomposition based on the curing reaction of the thermosetting resin component A, as illustrated in FIG. 7, the thermosetting resin component A and the high-molecular component B, which are evenly compatible and miscible with each other, are separated into the region b1 (reference number 5a in FIG. 7), wherein the concentration of the high-molecular component B is high, and the particulate structures a1 (reference number 2 in FIG. 7), wherein the concentration of the thermosetting resin component is high. As illustrated in FIG. 8, inside the separated particulate structures a1 (reference number 3 in FIG. 8), the second-stage spinodal decomposition is further caused, so that the inside is separated into the particulate structures a2 (reference number 3a in FIG. 8), which have the average diameter D2 smaller than the average diameter D1, and are higher in the concentration of the thermosetting resin component A than the particulate structures a1; and the region b3 (reference number 3b in FIG. 8), which is present in the particulate structures a1, is higher in the concentration of the high-molecular component B than the particulate structures a1, and is different from the particulate structures a2.

Moreover, in the region b1 also, the second-stage spinodal decomposition is caused, so that the region is separated into the region b2 (reference number 5b in FIG. 8), which is higher in the concentration of the high-molecular component B than the region b1 and the particulate structures a1; and the particulate structures a4 (reference number 4a in FIG. 8), which have the average diameter D6 smaller than the average diameter D1 of the particulate structures a1, and are higher in the concentration of the thermosetting resin component A than the regions b1 and b2.

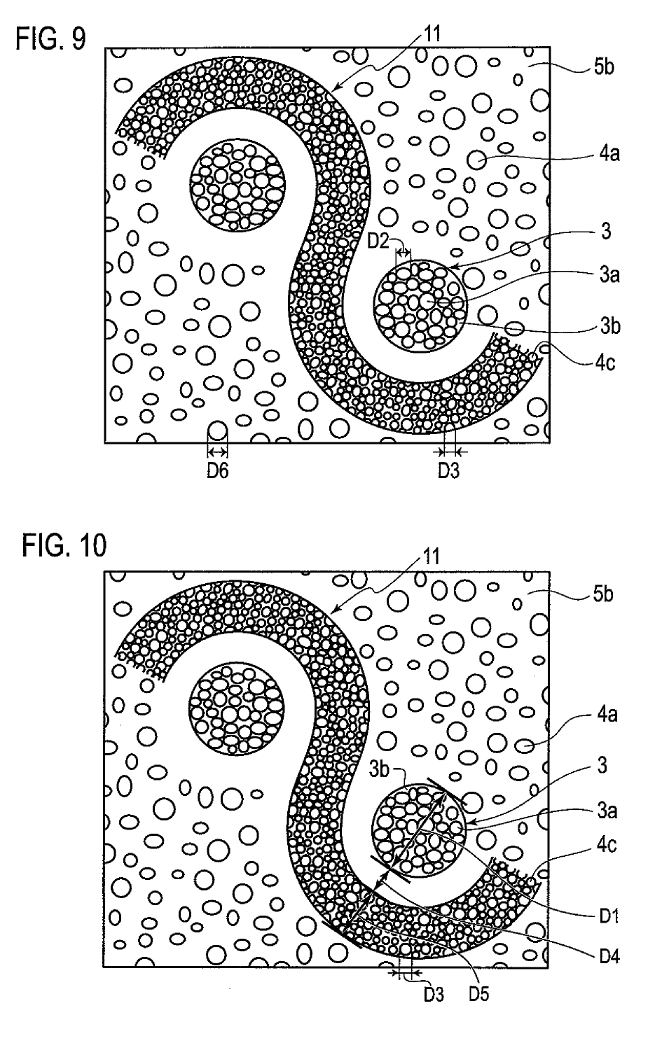

Thereafter, it appears that the third-stage spinodal decomposition is caused, so that as illustrated in FIG. 9, it is separated into the particle-continued structures and/or co-continuous-phase structures a3 (reference number 11 in FIG. 9) so as to surround the particulate structures a1 (reference number 3 in FIG. 9), wherein the structures a3 have the average diameter D3 smaller than the average diameter D1 of the particulate structures a1, and are higher in the concentration of the thermosetting resin component A than the region b2 (reference number 5b in FIG. 9).

In the same manner as about the adhesive compositions (A) to (C), the average diameter D1 of the particulate structures a1 is preferably 200 nm or more. The average diameter D1 is more preferably 500 nm or more, even more preferably 1 μm or more.

The average diameter D3 is not particularly limited as far as the diameter is smaller than the average diameter D1. In order to make the average diameter D3 smaller than the average diameter D1, it is advisable to use the above-mentioned individual components.

As illustrated in FIG. 10, when the average diameter of the particulate structures a1 (3) is represented by D1, the particle-continued structures and/or co-continuous-phase structures a3 of the particulate structure 4c, which are higher in the concentration of the thermosetting resin component A than the region b2 are shown by reference number 11, and the distance between the particulate structures al (3) and the particle-continued structures and/or co-continuous-phase structures a3 (11) is represented by D4, the distance D4 is set preferably into the range of 10 to 90% of the average diameter D1 of the particulate structures a1, more preferably into that of 30 to 70% thereof for the following purpose: when the adhesive composition is made into an adhesive layer, the composition gains such an excellent adhesive property that the composition can be used for thin-film bonding, wherein the thickness of the layer is 30 μm or less, and gains practical properties, such as heat resistance, crack resistance, and exudation resistance, which is a property that the adhesive less exudes.

In each of cases where the distance D2 is less than 10% of the average diameter D1 of the particulate structures a1 and is more than 90% of the average diameter D1 of the particulate structures a1, for example, the following improving function tends not to be sufficiently expressed: a function that when the adherend is peeled, the shape thereof is deformed or damaged, whereby peeling energy is relaxed so that the peel strength is improved.

For this reason, when the width of the particle-continued structures and/or co-continuous-phase structures a3 (11), which surround the particulate structures a1 (3), is represented by the width D5 as illustrated in FIG. 10, the width D5 is set preferably into the range of 10 to 200% of the average diameter D1 of the particulate structures a1, more preferably into that of 30 to 100% thereof.

The method for setting the distance D4 into the range of 10 to 90% of the average diameter D1 and the method for setting the width D5 into the range of 10 to 200% of the average diameter D1 are not particularly limited. The settings appear to be attained, for example, by setting the average diameter D1 of the particulate structures a1 formed by the first-stage spinodal decomposition to 200 nm or more.

In order to construct the adhesive composition (d), it is advisable to use the above-mentioned individual components.

The existences of the particulate structures a1; the region b2, wherein the concentration of the high-molecular component B is high; the particulate structures a2, which has the average diameter D2; and the particle-continued structures and/or co-continuous-phase structures a3 of the particulate structure 4c can be checked using a field emission type transmission electron microscope in the similar way to in the method for measuring the average diameter D1.

The methods for measuring the average diameter D3, the distance D4 and the width D5 are each performed in the same way as the method for structure-confirmation of the particulate structures in the adhesive composition (A). The method for adjusting the average diameter D1 in the adhesive composition (D) is performed in the same way as in the case of the adhesive composition (A).

The existences of the particulate structures a1, the structures a3 and the region b2 can be checked using a field emission type transmission electron microscope in the same way as in the method for measuring the average diameter D1. The concentration of the thermosetting resin component A and that of the high-molecular component B therein can also be checked, using the SVM image of the adhesive composition (A).

<Process for Producing the Adhesive Composition of the Invention, and Process for Producing an Adhesive-Composition-Containing Varnish>

The following adhesive composition of the invention is also a preferred embodiment of the invention: an adhesive composition wherein the thermosetting resin component A; the high-molecular component B, the amount of which being 100 to 900 parts by mass for 100 parts by mass of the thermosetting resin component A; and the curing agent component C, the amount of which being 0.5 to 2 times the chemical equivalent of the thermosetting resin component A; are incorporated into a solvent.

A process for producing the adhesive composition of the invention will be described hereinafter.

The process for producing the adhesive composition of the invention is a method of mixing or dissolving the thermosetting resin component A, the high-molecular component B, the curing agent component C, and any optional component. The method is not limited except this operation. Specific raw material components used in the adhesive composition of the invention, and specific use amounts thereof are as described above.

It is preferred to dissolve or disperse, into a solvent, the thermosetting resin component A, the high-molecular component B, and the hardener component C, which are essential components, and the optional component in appropriate amounts, thereby preparing a varnish since the mixing, dissolution or dispersion of the individual raw material components is made easy and a process for producing a bonding member by use of the adhesive composition of the invention can be made simple.

The solvent used to prepare the varnish is not particularly limited. It is preferred to use methyl ethyl ketone, acetone, methyl isobutyl ketone, 2-ethoxyethanol, toluene, xylene, butylcellosolve, methanol, ethanol, 2-methoxyethanol or the like, which has a low boiling point, considering the volatility thereof when a film is formed, and others.

For an improvement in properties of the painted film, and other purposes, a high boiling point solvent may be added, examples thereof including dimethylacetoamide, dimethylformamide, N-methylpyrrolidone, cyclohexanone, and γ-butyrolactone.

At this time, the boiling point of the solvent and the blend amount thereof cannot be particularly limited since they are decided dependently on a combination of the thermosetting resin component A with the curing agent component C. It is necessary that the solvent can be dried under the condition of a curing degree of the thermosetting resin component A that permits the thermosetting resin component A and the curing agent component C to be attracted to the adherend. They are preferably selected so as for the thermosetting resin component A not to start to undergo curing reaction.

The method for mixing, dissolving or dispersing the individual raw material components is not particularly limited, and may be a method using a kneading machine such as a dissolver, a static mixer, a homogenizer, an ultrasonic homogenizer, a paint shaker, a ball mill, a planetary mixer, a mixing rotor, a universal stirrer, a self-rotating and revolving stirrer, a crusher, or a three-axis roller. After the varnish is prepared, it is preferred to remove air bubbles in the varnish. From this viewpoint, a self-rotating and revolving stirrer is preferably used since the mixing, dissolution or dispersion, and the removal of the air bubbles can be simultaneously attained.

<Bonding Member of the Invention, and Process for Producing the Member>

The bonding member of the invention will be described hereinafter.

The bonding member of the invention is a member containing an adhesive layer obtained by using a varnish containing the adhesive composition of the invention and making the varnish into a film form.

A process for producing the bonding member of the invention is not particularly limited as far as it contains the step of forming the adhesive composition of the invention into a film form to obtain an adhesive layer. The process is preferably a process of dissolving or dispersing the adhesive composition of the invention to prepare a vanish, painting the vanish onto a support film and then heating the resultant to remove the solvent since the process is simple.

By peeling the support film when the member is used, only the adhesive layer may be used. The adhesive layer together with the support film is used and the film may be afterward removed.

This support film may be a plastic film such as a polyethylene terephthalate film, a polyimide film, a polyethylene film, a polypropylene film, or a polytetrafluoroethylene film. The plastic film may be used in the state that a surface thereof is subjected to peeling treatment.

An organic compound may also be used for the support film, typical examples of the compound including polyvinyl chloride, polyvinylidene chloride, polyvinyl alcohol, polyester, polyacrylonitrile, ethylene vinyl acetate copolymer, ethylene/vinyl alcohol copolymer, ethylene/methacrylic acid copolymer, polyimide, polyamide, polycarbonate, ionomer resin, and other film materials.

A known method may be used as the method for painting the varnish onto the support film. Examples thereof include dip coating, flow coating, spin coating, curtain coating, knife coating, roll coating, wire bar coating, doctor blade coating, spray coating, ultrasonic coating, gravure coating, screen printing, brush painting, and sponge painting.

The thickness of the adhesive layer in the bonding member of the invention is not particularly limited, and is set preferably into the range of 0.5 to 250 μm. If the thickness is less than 0.5 μm, the effect of relaxing the stress is poor so that the adhesive property tends to be lowered. If the thickness is more than 250 μm, economical efficiency is lost. From this viewpoint, the thickness is more preferably from 1 to 100 μm, even more preferably from 3 to 50 μm. About the adhesive layer in the bonding member of the invention, two or more layers may be adhered to each other to gain a desired thickness. In this case also, it is necessary that air bubbles do not come into gaps between the adhesive layers.

The adhesive layer in the bonding member of the invention may be used in the state that the layer is bonded to each of two surfaces of a core member. The thickness of the core member is not particularly limited, and is preferably from 5 to 200 μm. The material used for the core member is not particularly limited, and is preferably a heat resistant thermoplastic film, more preferably a heat resistant thermoplastic film having a softening temperature of 260° C. or higher. If a heat resistant thermoplastic film having a softening temperature lower than 260° C. is used as the core member, the bonding member may be peeled at a high temperature, for example, in solder reflow or the like. This heat resistant thermoplastic film may be a porous film to decrease the elasticity modulus of the bonding member.

For forming the adhesive layer on the core member, vanish may be made by dissolving or dispersing the adhesive composition into a solvent. When this vanish is painted onto a heat resistant thermoplastic film which is to be the core member and then the resultant is heated to remove the solvent, the adhesive layer can be formed on the heat resistant thermoplastic film.

As the method for the painting, the method described about the method for painting, onto the above-mentioned support film, the vanish, or some other method may be used.

When the vanish is painted onto both surfaces of the core member and then the resultant is heated to remove the solvent, a bonding member wherein adhesive layers are formed on both surfaces of the core member, respectively, can be produced. When the adhesive layers are formed onto both of the surfaces of the core member, respectively, it is preferred to protect the surfaces with cover films in such a manner that the adhesive layers on both the surfaces are not blocked onto each other.

In the bonding member wherein an adhesive layer is formed on each surface of the core member, which is obtained by painting the varnish onto the support film, heating the resultant to remove the solvent, thereby forming the adhesive layer onto the support film, and then adhering the adhesive layer onto each of the surfaces of the core member, the support film may be used as a cover film.

<Support Member of the Invention for Semiconductor Mounting, and Process for Producing the Member>

The support member of the invention for semiconductor mounting will be described hereinafter.

The support member of the invention for semiconductor mounting has the bonding member of the invention over a semiconductor element mounted surface of a support member.

The process for producing the support member of the invention for semiconductor mounting is not particularly limited as far as it comprises the step of using the bonding member of the invention on a semiconductor element mounted surface of a support member. The support member may be a lead frame having die pads, a ceramic substrate, an organic substrate or the like.

The ceramic substrate may be an alumina substrate, an aluminum nitride substrate or the like.

The organic substrate may be an FR-4 substrate wherein a glass cloth is impregnated with epoxy resin, a BT substrate impregnated with bismaleimide/triazine resin, a polyimide film substrate wherein a polyimide film is used as a base member, or the like.

About the form of the wiring, a single-sided wiring, double-sided wiring or multi level wiring structure, or any other structure may be used. If necessary, electrically-connected through holes or blind holes may be made.

When the wiring makes its appearance on the outside surface of a semiconductor device, it is preferred to lay a protective resin layer.

As the method for adhering the bonding member to the support member, a method of cutting the bonding member into a predetermined shape and bonding the cut bonding member thermally onto a desired position of the support member is general. However, the method is not limited thereto.

<Semiconductor Device of the Invention, and Process for Producing the Device>

The semiconductor device of the invention will be described hereinafter.

The semiconductor device of the invention is a device wherein the bonding member of the invention is used to bond a semiconductor element and a support member, or the support member of the invention for semiconductor mounting is used.

The process for producing the semiconductor of the invention is not particularly limited as far as the bonding member of the invention is used to bond a semiconductor element and a support member to each other, or the support member of the invention for semiconductor mounting is used. About a semiconductor device wherein a semiconductor element and a support member are bonded to each other through the bonding member of the invention, a process of arranging the bonding member of the invention between a semiconductor element and a wiring board which is to be a support member so as to direct the adhesive layer of the bonding member onto the semiconductor element side, and then compressing the members thermally may be used.

It may be allowed to put a semiconductor element onto the support member for semiconductor mounting, which has the bonding member, and then compress the members thermally. It is preferable to laminate the bonding member and a dicing tape onto a semiconductor element, cut the semiconductor element and the bonding member into chips, and then bond a circuit-attached substrate onto each of the chips through the bonding member since the step of adhering the bonding member onto each of the chips can be omitted.

The structure of the semiconductor device of the invention may be a manner of adopting a structure wherein electrodes of a semiconductor element and a wiring board which is to be a support member are bonded to each other by wire bonding, a manner of adopting a structure wherein electrodes of a semiconductor element and a wiring board which is to be a support member are bonded to each other by inner lead bonding of tape automated bonding (TAB), or some other manner.

In the process for producing a semiconductor device wherein a semiconductor element and a circuit-attached substrate or circuit-attached film are bonded to each other through the bonding member, it is advisable in connection with conditions for the thermal compression to embed the bonding member in the circuit on the wiring board without generating any gap, and adhere the bonding member thereto under conditions of a temperature, a load, and a period that permit the bonding member to express a sufficient adhesive property. A load is preferably is 196 kPa or less, and is more preferably 98 kPa or less since the chip is not easily damaged.

The semiconductor element may be an ordinary semiconductor element, such as an IC, LSI, or VLSI.

Thermal stress generated between a semiconductor element and a support member is remarkable when a difference in area between the semiconductor element and the support member is small. In the semiconductor device of the invention, by use of the adhesive composition of the invention, which has a low elasticity modulus, for the bonding member of the invention, such heat stress is relaxed so that the reliability can be certainly kept. The advantageous effect is very effectively exhibited when the area of the semiconductor element is 70% or more of that of the support member.

In the semiconductor device wherein a difference in area between its semiconductor element and its support member is small as described above, an external connection terminal is located into an area form in many cases.

A characteristic of the bonding member of the invention is a characteristic that volatilized components from the adhesive layer can be restrained in any step in which heating is conducted, such as the step of compressing the bonding member thermally in a desired location of the support member, or the step of making a connection by wire bonding.

### EXAMPLES

Hereinafter, the invention will be more specifically described by way of examples; however, the invention is not limited to these examples.

Blendings and evaluations described below were conducted in the atmosphere within the range of 18 to 25° C. temperature at room temperature.

<Production of Adhesive Compositions, and Production of Sample Bonding Members for Evaluation>

### Example 1

A bisphenol A type epoxy resin (trade name: YD-8125, manufactured by Tohto Kasei Co., Ltd., weight-average molecular weight: 340, epoxy equivalent: 173 g/eq) as a thermosetting resin component A was dissolved into methyl ethyl ketone to give a concentration of 70% by mass. In this way, an epoxy resin solution (A1) was yielded.

A 15% by mass solution of an acrylic copolymer, as a high-molecular component B, which contained 3% by mass of glycidyl methacrylate as a copolymerizable component in methyl ethyl ketone (trade name of the solution: HTR-860P-3, manufactured by Nagase ChemteX Corp., weight-average molecular weight: 800,000) is called an acrylic copolymer solution (B).

4,4′-Diaminodiphenylmethane (manufactured by Tokyo Chemical Industry Co., Ltd., amine equivalent: 49.6) as a curing agent component C was dissolved into methyl ethyl ketone to give a concentration of 60% by mass. In this way, an amine solution (C1) was yielded.

Into a screw tube was encapsulated 2.15 g of the epoxy resin solution (A1), 30.00 g of the acrylic copolymer solution (B), and 0.71 g of the amine solution (C1), and then a mixing rotor was used to stir and mix the components at 80 rotations/min for 18 hours. In this way, an adhesive composition I was yielded.

The adhesive composition I was painted onto a polyimide film having a thickness of 50 μm (trade name: UPILEX 50-S, manufactured by Ube Industries, Ltd.) as an adherend, and the composition was heated and dried at 60° C. for 30 minutes to form a painted film wherein the film thickness of the adhesive composition I was 50 μm. Thereafter, the resultant was covered, on the adhesive composition I side thereof; with the same polyimide film not to leave any air bubble. In this way, an adherend-adhered sample bonding member I was yielded.

### Example 2

Hexamethylenediamine (manufactured by Nacalai Tesque, Inc., amine equivalent: 29.1) as a curing agent component C was dissolved into methyl ethyl ketone to give a concentration of 60% by mass. In this way, an amine solution (C2) was yielded.

Into a screw tube was encapsulated 2.25 g of the epoxy resin solution (A1), 30.00 g of the acrylic copolymer solution (B), 0.38 g of the amine solution (C1), which are yielded in Example 1, and 0.22 g of the amine solution (C2) yielded as described above, and then a mixing rotor was used to stir and mix the components at 80 rotations/min for 18 hours. In this way, an adhesive composition II was yielded.

The adhesive composition II and a polyimide film having a thickness of 50 μm (trade name: UPILEX 50-S, manufactured by Ube Industries, Ltd.) as an adherend were used to make the same operation as in Example 1 to yield an adherend-adhered sample bonding member II.

### Example 3

The adhesive composition II was painted onto a polyimide film having a thickness of 50 μm (trade name: UPILEX 50-S, manufactured by Ube Industries, Ltd.) as an adherend, and the composition was heated and dried at 60° C. for 30 minutes to form a painted film wherein the film thickness of the adhesive composition II was 10 μm. Thereafter, the resultant was covered, on the adhesive composition I side thereof; with the same polyimide film not to leave any air bubble. In this way, an adherend-adhered sample bonding member III was yielded.

### Comparative Example 1

A cresol Novolak type epoxy resin (trade name: YDCN-703, manufactured by Tohto Kasei Co., Ltd., weight-average molecular weight: 1723, epoxy equivalent: 209 g/eq) as a thermosetting resin component A was dissolved into methyl ethyl ketone to give a concentration of 70% by mass. In this way, an epoxy resin solution (A2) was yielded.

Into a screw tube was encapsulated 2.23 g of the epoxy resin solution (A2) yielded as described above, 30.00 g of the acrylic copolymer solution (B) used in Example 1, and 0.61 g of the amine solution (C1) yielded in Example 1, and then a mixing rotor was used to stir and mix the components at 80 rotations/min for 18 hours. In this way, an adhesive composition III was yielded.

The adhesive composition III was painted onto a polyimide film having a thickness of 50 μm (trade name: UPILEX 50-S, manufactured by Ube Industries, Ltd.) as an adherend, and the composition was heated and dried at 60° C. for 30 minutes to form a painted film wherein the film thickness of the adhesive composition III was 50 μm. As a result, it was observed visually that in the adhesive composition III, the cresol Novolak type epoxy resin and the acrylic copolymer were separated from each other so as to be white turbidity although the cresol Novolak type epoxy resin was not cured.

The adhesive composition III and a polyimide film having a thickness of 50 μm (trade name: UPILEX 50-S, manufactured by Ube Industries, Ltd.) as an adherend were used to make the same operation as in Example 1 to yield an adherend-adhered sample bonding member IV

### Comparative Example 2

Into a screw tube was encapsulated 20.04 g of the epoxy resin solution (A1), 30.00 g of the acrylic copolymer solution (B), and 6.62 g of the amine solution (C1), which are yielded in Example 1, and then a mixing rotor was used to stir and mix the components at 80 rotations/min for 18 hours. In this way, an adhesive composition IV was yielded.

The adhesive composition IV was painted onto a polyimide film having a thickness of 50 μm (trade name: UPILEX 50-S, manufactured by Ube Industries, Ltd.) as an adherend, and the composition was heated and dried at 60° C. for 30 minutes to form a painted film wherein the film thickness of the adhesive composition IV was 50 μm. As a result, it was observed visually that in the adhesive composition IV, the bisphenol A type epoxy resin and the acrylic copolymer were separated from each other so as to be white turbidity although the bisphenol A type epoxy resin was not cured.

The adhesive composition IV and a polyimide film having a thickness of 50 μm (trade name: UPILEX 50-S, manufactured by Ube Industries, Ltd.) as an adherend were used to make the same operation as in Example 1 to yield an adherend-adhered sample bonding member V.

### Comparative Example 3

1-Cyanoethyl-2-phenylimidazole (trade name: CUREZOL 2PZ-CN, manufactured by Shikoku Chemicals Corp., molecular weight: 197) as a curing agent component C was dissolved into methyl ethyl ketone to give a concentration of 60% by mass. In this way, an amine solution (C3) was yielded.

Into a screw tube was encapsulated 2.76 g of the epoxy resin solution (A1), 30.00 g of the acrylic copolymer solution (B), which are yielded in Example 1, and 0.54 g of the amine solution (C3) yielded as described above, and then a mixing rotor was used to stir and mix the components at 80 rotations/min for 18 hours. In this way, an adhesive composition V was yielded.

The same operation as in Example 1 was made except that the adhesive composition V was used, so as to yield an adherend-adhered sample bonding member VI.

### Comparative Example 4

2-Methylimidazole (manufactured by Aldrich Co., molecular weight: 82) as a curing agent component C was dissolved into methyl ethyl ketone to give a concentration of 60% by mass. In this way, an amine solution (C4) was yielded.

Into a screw tube was encapsulated 2.76 g of the epoxy resin solution (A1), 30.00 g of the acrylic copolymer solution (B), which are yielded in Example 1, and 0.54 g of the amine solution (C3) yielded in Comparative Example 3, and then a mixing rotor was used to stir and mix the components at 80 rotations/min for 18 hours. In this way, an adhesive composition VI was yielded.

The same operation as in Example 1 was made except that the adhesive composition VI was used, so as to yield an adherend-adhered sample bonding member VII.

<Production of a Bonding Member>

### Example 4

The adhesive composition I yielded in Example 1 was used to produce a bonding member as described below.

The adhesive composition I was first painted onto a polyimide film having a thickness of 12.5 μm (trade name: UPILEX 12.5-SN, manufactured by Ube Industries, Ltd.) as a supporting film, and the composition was heated and dried at 60° C. for 30 minutes to form a painted film wherein the film thickness of the adhesive composition I was 50 μm. Thereafter, the resultant was covered, on the adhesive composition I side thereof, with a gold foil piece (manufactured by the Nilaco Corp.) having a thickness of 10 μm, as another supporting film, not to leave any air bubble. The resultant was heated to cure the composition at a temperature of 120° C. for 1 hour. In this way, a bonding member VIII was yielded.

<Evaluating Methods>

The evaluating methods will be described in detail.

Evaluations described below were made after the adherend-adhered sample bonding members I to VII yielded as described above were sufficiently heated and cured at a temperature of 120 to 170° C. for 1 hour. The bonding member VIII yielded in Example 4 was also evaluated.

(1) Evaluation of the Uneven Distribution Ratio of Particulate Structures

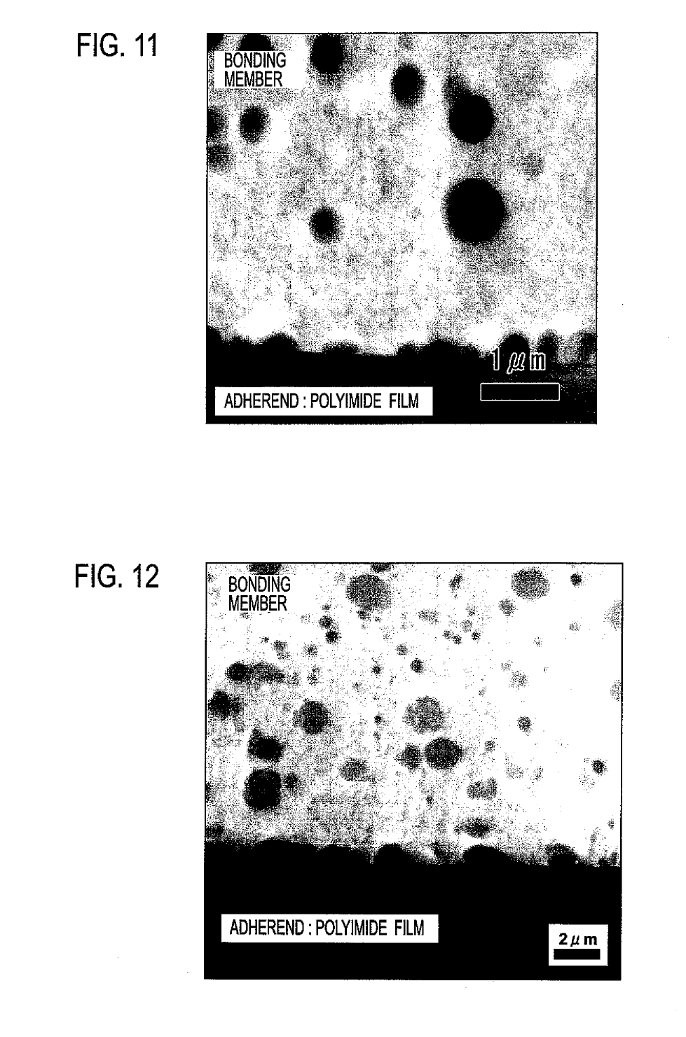

In order to evaluate the uneven distribution ratio of the structure wherein particulate structures are formed in a large amount near a surface of any adhesive composition contacting an adherend than inside the adhesive composition, that is, the uneven distribution ratio of particulate structures toward the side of an adherend, a cured adherend-adhered sample bonding member or support-film-adhered bonding member was cut orthogonally to the adherend into a piece of 100 nm thickness with a diamond knife. A field emission type transmission electron microscope was used to photograph, as an image having density difference, a structure near the interface between the adherend and the adhesive composition cured product in the resultant orthogonal cross section. Data on this image were digitalized, and then the ratio of the area occupied by the particulate structures wherein the thermosetting resin component A concentration is higher than the surrounding in a given area was obtained. Obtained field emission type transmission electron microscopic images are shown in FIGS. 11 to 14.

FIG. 11 is a field emission type transmission electron microscopic image of the orthogonal cross section of the adherend-adhered sample bonding member I obtained in Example 1. As is evident from FIG. 11, it is understood from the blend ratios in the adhesive composition I that particulate structures having a dark color, which are generated by a spinodal decomposition, are a component wherein the concentration of the bisphenol A type epoxy resin is high. It is understood that the particulate structures gather near the surface of the polyimide film, which is the adherend, so that the particulate structures are formed in an evidently larger amount therein than inside the bonding member.

FIG. 12 is a field emission type transmission electron microscopic image of the orthogonal cross section of the adherend-adhered sample bonding member H obtained in Example 2. As is evident from FIG. 12, it is understood from the blend ratios in the adhesive composition II that particulate structures having a dark color, which are generated by a spinodal decomposition, are a component wherein the concentration of the bisphenol A type epoxy resin is high. It is understood that the particulate structures gather near the surface of the polyimide film, which is the adherend, so that the particulate structures are formed in an evidently larger amount therein than inside the bonding member.

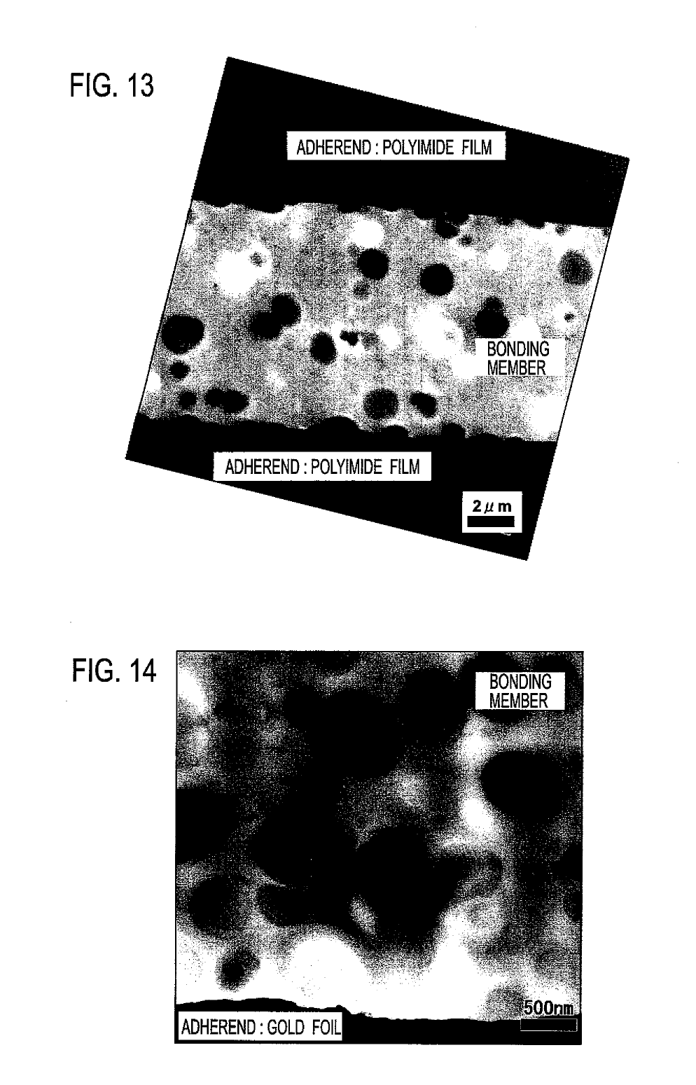

FIG. 13 is a field emission type transmission electron microscopic image of the orthogonal cross section of the adherend-adhered sample bonding member III obtained in Example 3. As is evident from FIG. 13, it is understood from the blend ratios in the adhesive composition II that particulate structures having a dark color, which are generated by a spinodal decomposition, are a component wherein the concentration of the bisphenol A type epoxy resin is high. It is understood that the particulate structures gather near the surface of the polyimide film, which is the adherend, so that the particulate structures are formed in an evidently larger amount therein than inside the bonding member.

FIG. 14 is a field emission type transmission electron microscopic image of the orthogonal cross section of the adherend-adhered sample bonding member VIII obtained in Example 4. As is evident from FIG. 14, it is understood from the blend ratios in the adhesive composition I that particulate structures having a dark color, which are generated by a spinodal decomposition, are a component wherein the concentration of the bisphenol A type epoxy resin is high. It is understood that three or more layers of the particulate structures gather near the surface of the gold foil surface, which is the adherend, so that the particulate structures are formed in an evidently larger amount therein than inside the bonding member.

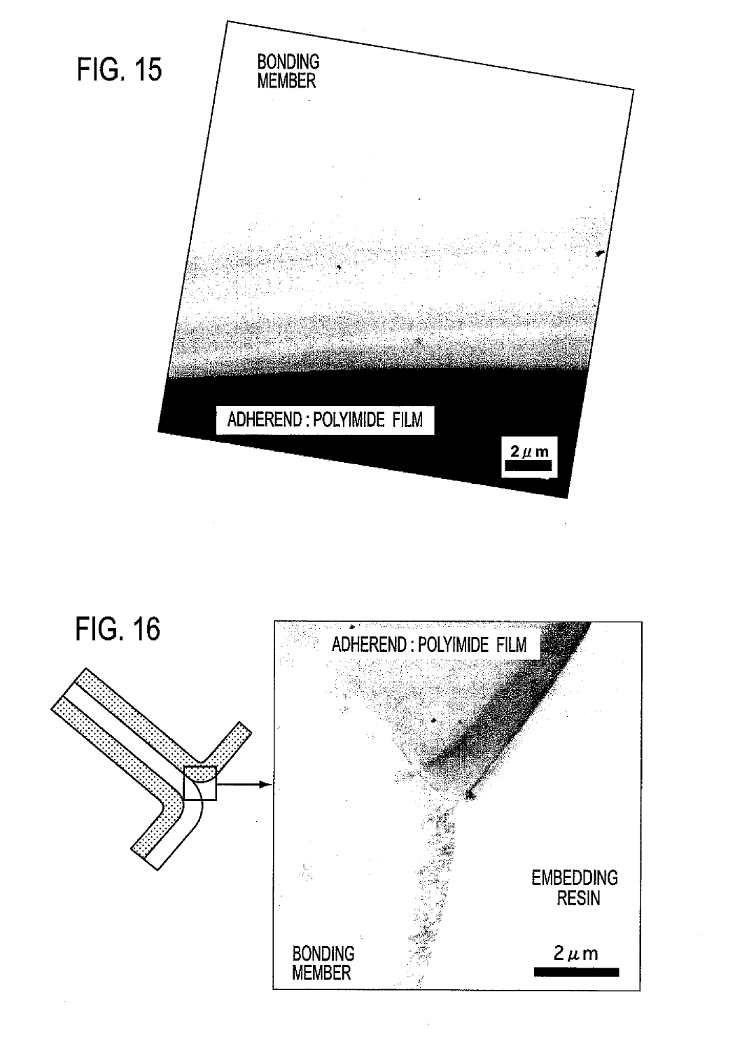

FIG. 15 is a field emission type transmission electron microscopic image of the orthogonal cross section of the adherend-adhered sample bonding member VI obtained in Comparative Example 3. As is evident from FIG. 15, it is understood from the blend ratios in the adhesive composition V that particulate structures having a dark color, which are generated by spinodal decomposition, are a component wherein the concentration of the bisphenol A type epoxy resin are high. The particulate structures have a size of about 200 nm or less, and separation thereof from other regions, wherein the concentration of the acrylic copolymer is high, is less perfect compared to Examples 1 to 3.

As understood from FIG. 15, the particulate structures that are a component wherein the concentration of the bisphenol A type epoxy resin is high do not gather near the surface of the polyimide film, which is the adherend, so that the amount thereof is hardly different from that inside the bonding member.

According to an observation of the cross section of the adherend-adhered sample bonding member VII obtained in Comparative Example 4 with the field emission type transmission electron microscope, the particulate structures that were a component wherein the concentration of the bisphenol A type epoxy resin was high did not gather, either, near the surface of the polyimide film, which was the adherend, so that the structure near the surface was hardly different from that inside the bonding member.

(2) Evaluation of the Average Diameter D1 and the Area Fraction of the Particulate Structures

From each of the field emission type transmission electron microscopic images, under conditions that the area fraction of the particulate structures to the other region is represented by AF, the average diameter of the particulate structures is represented by D1, the area fraction of a region having distances of 0 to D1 from the adherend surface is represented by AFI, and the area fraction of a region having distances of D1 to D1×2 from the adherend surface is represented by AF2, the ratio between the area fractions, which is the uneven distribution ratio of the particulate structures toward the adherend, i.e., the value of AF1/AF2 was calculated out.

(3) Adhesive Property

Each of the cured adherend-adhered sample bonding members was made into a test piece having a shape of 10 cm×10 cm size; the test piece was peeled off into a T-shaped look at a rate of 0.50 mm/s; and the strength at the time of the peeling was measured as the adhesive property. Valuations thereof are as follows: any member wherein the peel strength was less than 100 N/m is represented by x, any member wherein the peel strength was 100 N/m or more and less than 200 N/m is represented by Δ, and any member wherein the peel strength was 200 N/m or more is represented by O. About the support-film-adhered bonding member VIII yielded in Example 4, no evaluation was made since the strength of the gold foil piece used as the support film was insufficient.

(4) Crack Resistance

Each of the cured adherend-adhered sample bonding members was made into a test piece having a shape of 10 cm×10 cm size; a tensile test was made to break the test piece; and the strength at the time of the breaking was measured as the crack resistance. Valuations thereof are as follows: any member wherein the breaking strength was less than 5 MPa is represented by x, any member wherein the breaking strength was from 5 to 10 MPa is represented by Δ, and any member wherein the breaking strength was 10 MPa or more is represented by O. About the support-film-adhered bonding member VIII yielded in Example 4, no evaluation was made since the strength of the gold foil piece used as the support film was insufficient.

(5) Heat Resistance

Each of the cured adherend-adhered sample bonding members was cut into 5 pieces of 30 mm×30 mm size, and the pieces were put onto a hot plate of 260° C. temperature, so as to examine the generation of abnormalities, such as swelling, for a period up to 60 seconds. Valuations thereof are as follows: any member about which an abnormality was observed in all of the samples is represented by x, any member about which an abnormality was generated in one or more of the samples and no abnormality was generated in the other sample(s) is represented by Δ, and any member about which an abnormality was not observed at all in any one of the samples is represented by O.

(6) Exudation Resistance

Each of the cured adherend-adhered sample bonding members was made into a test piece having a shape of 30 cm×30 cm size. A hot press was used to press the test piece at 200° C. and at 10 atm. for 20 minutes. It was then observed with an optical microscope whether or not the resin exuded from the edge of the test piece. Valuations thereof are as follows: any member wherein the resin did not exude is represented by O, and any member wherein the resin exuded is represented by x.

(7) Evaluation of a Change in the Structure Based on Adherend-Peeling

The sample about which the evaluation in the item “(3) Adhesive property” had been made, wherein the adherend was partially peeled, was wrapped by use of a normal-temperature curable epoxy embedding resin (trade names: EPOFIX RESIN and EPOFIX HARDENER). The resultant was then allowed to stand still at room temperature for 2 days, so as to be hardened. The resultant was cut orthogonally to the adherend with a diamond knife. The electron emission type transmission electron microscope was used to observe the peel-starting point of the orthogonal cross section. In FIG. 16 is shown an electron emission type transmission electron microscopic image of the adherend-adhered sample bonding member in Example 1.

From FIG. 16, it is understood that pores are generated by expansion stress in the region of the high-molecular component B (that is, the rubbery component) around the particulate structures formed largely near the surface of the polyimide film, which is the adherend, and further the particulate structures are lengthily extended at the peel-starting point so that the structures undergo plastic deformation finally, so as to be divided into fine fragments. According to this, in the rubbery component region, expansion stress is consumed, and further a large quantity of peeling energy is consumed for the plastic deformation of the particulate structures so that an excellent adhesive property was expressed.

This phenomenon was recognized in the same manner as in the adherend-adhered sample bonding member II of Example 2 and the adherend-adhered sample bonding member III of Example 3.

On the other hand, in the adherend-adhered sample bonding member VI of Comparative Example 3 and the adherend-adhered sample bonding member VII of Comparative Example 4, the generation of such pores and such fragmentation of the particulate structures in the rubbery component region were not recognized near the adherend.

(8) Evaluations of Phase Structures of the Particulate Structures a1, a2 and a4, and the Regions b2 and b3

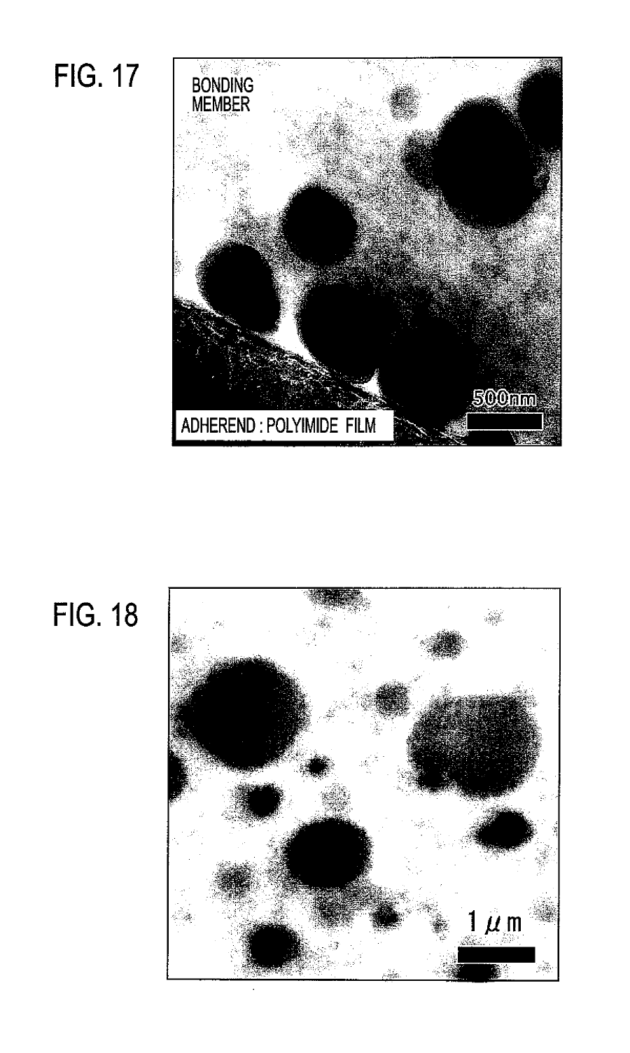

The nature that separation was made into the particulate structures a1, a2 and a4, and the regions b2 and b3 was evaluated as follows: First, each of the cured adherend-adhered sample bonding members was cut orthogonally to the adherend with a diamond knife, and then the field emission type transmission electron microscope was used to observe the phase structure of the orthogonal cross section. The resultant field emission type transmission electron microscopic images are shown in FIGS. 17 to 20.

From each of the images, the average diameter D1 of the particulate structures a1, the average diameter D2 of the particulate structures a2, and the average diameter D6 were obtained. The proportion of the average diameter D2 and the average diameter D6 to the average diameter D1 was calculated, and then represented in the unit of %. The results are shown in Table 2.

FIG. 17 is the field emission type transmission electron microscopic image of the cross section of the adherend-adhered sample bonding member I yielded in Example 1. According to FIG. 17, it is understood from the blend ratios in the adhesive composition I that the particulate structures a1 having a dark color, which are generated by a spinodal decomposition, are a component wherein the concentration of the bisphenol A type epoxy resin is high.

It is understood that in the dark-color particulate structures a1, and in the region b1 other than the structures a1, wherein the concentration of the acrylic copolymer is high, smaller particulate structures a2, and particulate structures a4 are formed by a second-stage spinodal decomposition.

FIG. 18 is the field emission type transmission electron microscopic image of the cross section of the adherend-adhered sample bonding member II yielded in Example 2. According to FIG. 18, it is understood from the blend ratios in the adhesive composition II that the particulate structures a1 having a dark color, which are generated by a spinodal decomposition, are a component wherein the concentration of the bisphenol A type epoxy resin is high.

It is understood that in the dark-color particulate structures a1, and in the region b1 other than the structures a1, wherein the concentration of the acrylic copolymer is high, smaller particulate structures a2, and particulate structures a4 are formed by a second-stage spinodal decomposition.

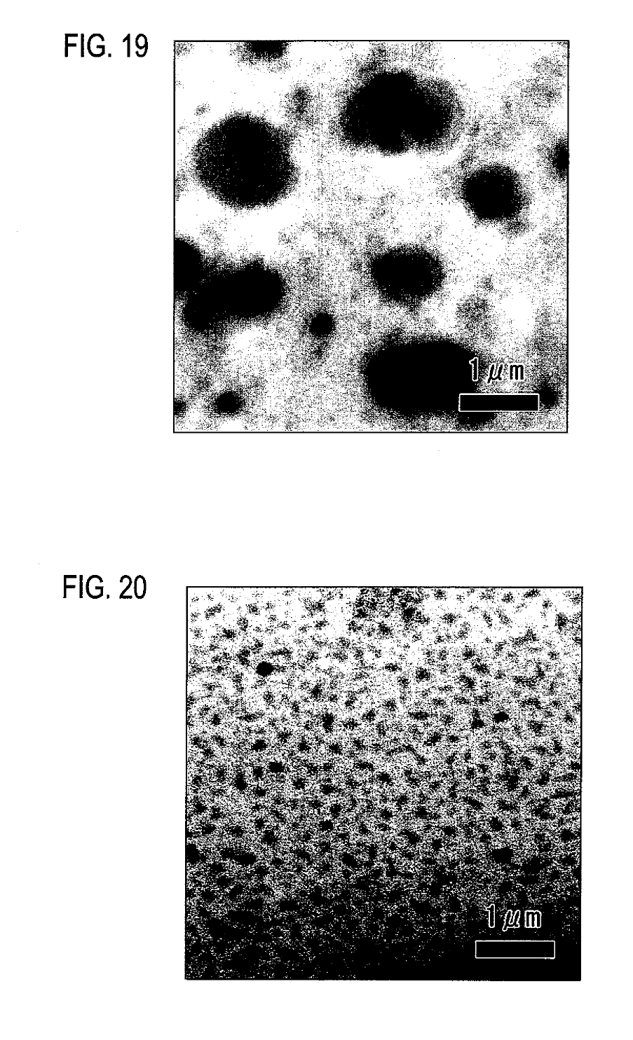

FIG. 19 is the field emission type transmission electron microscopic image of the cross section of the adherend-adhered sample bonding member III yielded in Example 3. According to FIG. 19, it is understood from the blend ratios in the adhesive composition II that the particulate structures a1 having a dark color, which are generated by a spinodal decomposition, is a component wherein the concentration of the bisphenol A type epoxy resin was high.

It is understood that in the dark-color particulate structures a1, and in the region b1 other than the structures a1, wherein the concentration of the acrylic copolymer is high, smaller particulate structures a2, and particulate structures a4 are formed by a second-stage spinodal decomposition.

FIG. 20 is the field emission type transmission electron microscopic image of the cross section of the adherend-adhered sample bonding member VI yielded in Comparative Example 3. According to FIG. 20, it is understood from the blend ratios in the adhesive composition V that the particulate structures al having a dark color, which are generated by a spinodal decomposition, is a component wherein the concentration of the bisphenol A type epoxy resin was high.

The particulate structures a1 have a size of about 200 nm or less, and separation thereof from other regions, wherein the concentration of the acrylic copolymer is high, is less perfect compared to Examples 1 to 3.

In the dark-color particulate structures a1, and in the region b1 other than the structures a1, wherein the concentration of the acrylic copolymer was high, smaller particulate structures a2, and particulate structures a4 resulting from a second-stage spinodal decomposition were not recognized.

According to an observation of the cross section of the adherend-adhered sample bonding member VII yielded in Comparative Example 4 with the field emission type transmission electron microscope, in the dark-color particulate structures a1, and in the region b1 other than the structures a1, wherein the concentration of the acrylic copolymer was high, smaller particulate structures a2, and particulate structures a4 resulting from a second-stage spinodal decomposition were not recognized, either.

(9) Evaluations of the Particulate Structures a1 and a3, and the Region b2

Separation into the particulate structures a1 and a3, and the region b2 was checked in the same way as in the item (8).

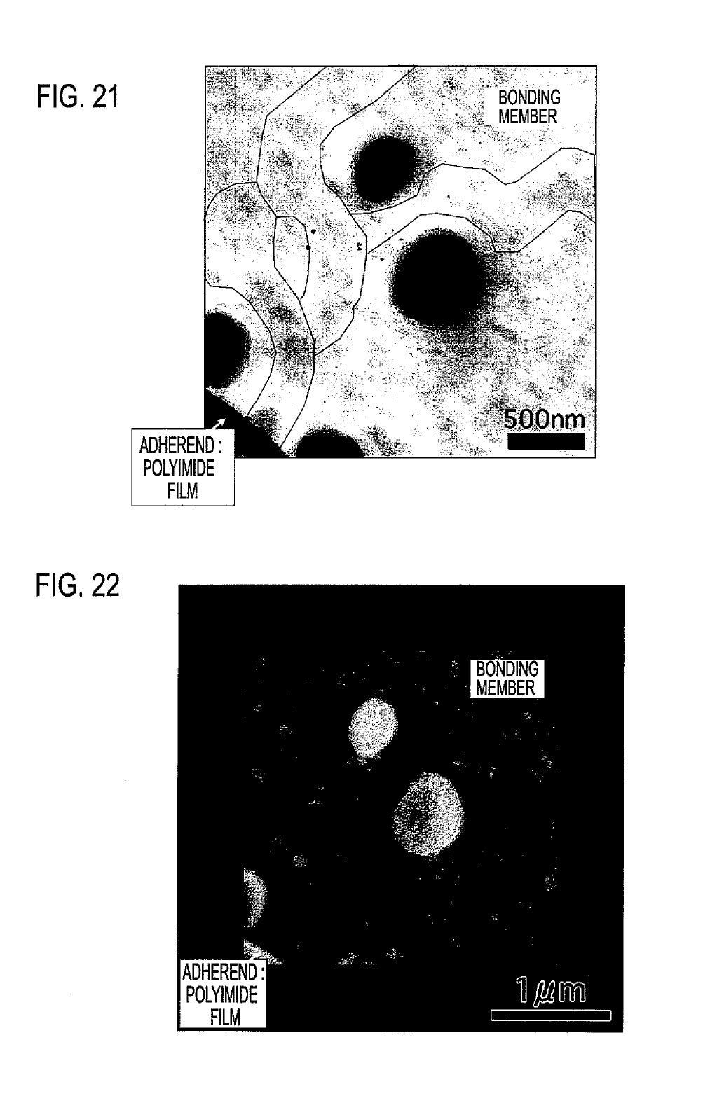

The field emission type transmission electron microscope was used to check separation, based on a third stage spinodal decomposition, into the particle-continued structures and/or co-continuous-phase structures a3, which had an average diameter D3 smaller than the average diameter D1 of the particulate structures a1 and were high in the concentration of the thermosetting resin component A so as to surround the particulate structures a1. The resultant field emission type transmission electron microscopic images are shown in FIG. 20, and FIGS. 21 to 25.

FIG. 21 is a field emission type transmission electron microscopic image of the cross section of the adherend-adhered sample bonding member I yielded in Example 1. As illustrated in FIG. 21, it is understood from the blend ratios in the adhesive composition I that in the dense-color particulate structures a1 generated by a spinodal decomposition, the concentration of the bisphenol A type epoxy resin component is high.

It is understood that as shown lines, structures appearing to be structures separated into smaller particle-continued structures or co-continuous-phase structures a3 wherein the concentration of the bisphenol A type epoxy resin component is high are formed to surround the dense-color particulate structures a 1.

FIG. 22 is an image obtained by inverting white and black in FIG. 21 to each other by image processing in order to make clear the structures appearing to be structures separated into the smaller particle-continued structures or co-continuous-phase structures, wherein the concentration of the bisphenol A type epoxy resin component is high. As illustrated in FIG. 21, it is clearly understood that the structures appearing to be structures separated into the smaller particle-continued structures or co-continuous-phase structures, wherein the concentration of the bisphenol A type epoxy resin component is high, are formed to surround the particulate structures wherein the concentration of the bisphenol A type epoxy resin is high.

The distance D4 was 49% of the average diameter D1, the distance D4 being the distance between the average diameter D1 and the particle-continued structures and/or co-continuous-phase structures a3, wherein the concentration of the thermosetting resin component A was high, formed to surround the particulate structures a1.

The width D5 of the particle-continued structures and/or co-continuous-phase structures a3, wherein the concentration of the thermosetting resin component A was high, was 49% of the average diameter D1.

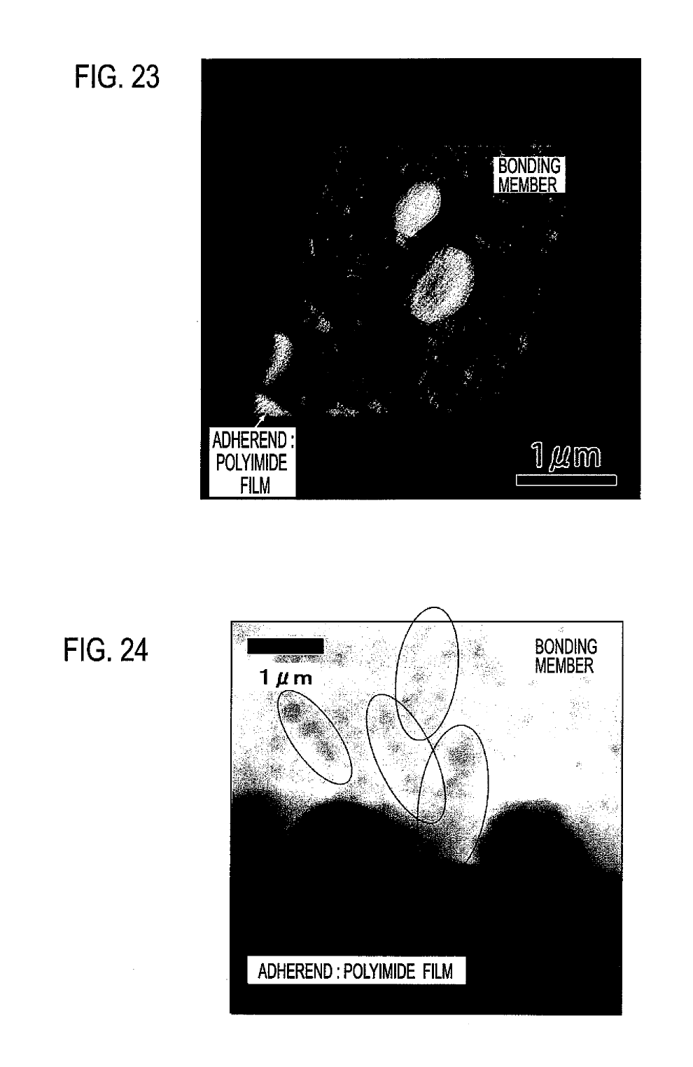

FIG. 23 is an image wherein FIG. 22 is inclined into the form of a three-dimensional image in order to make clear the particle-continued structures and/or co-continuous-phase structures a3, wherein the concentration of the thermosetting resin component A is high.

As illustrated in FIG. 23, it is clearly understood that the particle-continued structures and/or co-continuous-phase structures a3, wherein the concentration of the thermosetting resin component A is high, are formed to surround the particulate structures a1.

FIG. 24 is a field emission type transmission electron microscopic image of the cross section of the adherend-adhered sample bonding member H yielded in Example 2. As illustrated in FIG. 24, it is understood from the blend ratios in the adhesive composition II that in the dense-color particulate structures a1 generated by a spinodal decomposition, the concentration of the bisphenol A type epoxy resin component is high.

It is understood that as shown lines, structures appearing to be structures separated into smaller particle-continued structures or co-continuous-phase structures wherein the concentration of the bisphenol A type epoxy resin component is high are formed to surround the dense-color particulate structures a1.

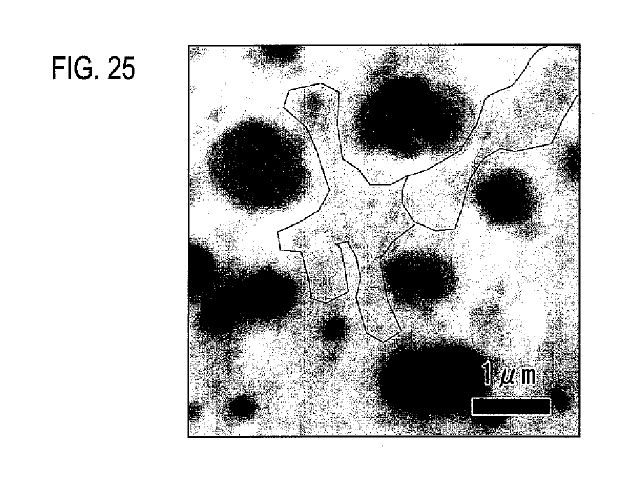

FIG. 25 is a field emission type transmission electron microscopic image of the cross section of the adherend-adhered sample bonding member III yielded in Example 3. As illustrated in FIG. 25, it is understood from the blend ratios in the adhesive composition II that in the dense-color particulate structures generated by a spinodal decomposition, the concentration of the bisphenol A type epoxy resin component is high.

It is understood that as shown lines, structures appearing to be structures separated into smaller particle-continued structures or co-continuous-phase structures wherein the concentration of the bisphenol A type epoxy resin component is high are formed to surround the dense-color particulate structures a1.

FIG. 20 is a field emission type transmission electron microscopic image of the cross section of the adherend-adhered sample bonding member VI yielded in Comparative Example 3. As illustrated in FIG. 20, it is understood from the blend ratios in the adhesive composition VI that the dense-color particulate structures a1 generated by a spinodal decomposition are a component wherein the concentration of the bisphenol A type epoxy resin component is high.

The particulate structures a1, wherein the concentration of the bisphenol A type epoxy resin component is high, have a size of about 200 nm or less, and separation thereof from other regions, wherein the concentration of the acrylic copolymer is high, is less perfect compared to Examples 1 to 3.

The structures a3 were unable to be recognized, the structures 3a appearing to be structures separated into smaller particle-continued structures or co-continuous-phase structures wherein the concentration of the bisphenol A type epoxy resin component was high, the structures being formed to surround the particulate structures a1, wherein the concentration of the bisphenol A type epoxy resin was high.

Also according to an observation of the cross section of the adherend-adhered sample bonding member VII yielded in Comparative Example 4 with the field emission type transmission electron microscope, the structures a3 were unable to be recognized, the structures 3a appearing to be structures separated into smaller particle-continued structures or co-continuous-phase structures wherein the concentration of the bisphenol A type epoxy resin component was high, the structures being formed to surround the particulate structures a1, wherein the concentration of the bisphenol A type epoxy resin was high.

These results are shown in Tables 1 to 2.

TABLE 1

| | | | | | | Comparative | Comparative | Comparative | Comparative |
|---|---|---|---|---|---|---|---|---|---|
| | | Example 1 | Example 2 | Example 3 | Example 4 | Example 1 | Example 2 | Example 3 | Example 4 |
| Separation before curing | | Not caused | Not caused | Not caused | Not caused | Caused | Caused | Not caused | Not caused |
| Uneven | Amount of the | Large | Large | Large | Large | — | — | Hardly | Hardly |
| distribution | particulate structures | | | | | | | changed | changed |
| ratio of the | near the adherend | | | | | | | | |
| particulate | Ratio between the | 2 or more | 2 or more | 2 or more | 1.07 | — | — | 1.00 | 1.03 |
| structures | area fractions of the | | | | | | | | |
| toward the | particulate structures | | | | | | | | |
| adherend | (AF1/AF2) | | | | | | | | |

| | | | | | | | | |
|---|---|---|---|---|---|---|---|---|
| Adhesive property | ∘ | ∘ | ∘ | — | x | x | x | x |
| Crack resistance | ∘ | ∘ | ∘ | — | x | x | x | Δ |
| Heat resistance | ∘ | ∘ | ∘ | ∘ | ∘ | ∘ | ∘ | x |
| Exudation resistance | ∘ | ∘ | ∘ | ∘ | ∘ | ∘ | ∘ | x |

TABLE 2

| | | | | | | Comparative | Comparative | Comparative | Comparative |
|---|---|---|---|---|---|---|---|---|---|
| | | Example 1 | Example 2 | Example 3 | Example 4 | Example 1 | Example 2 | Example 3 | Example 4 |
| Separation before curing | | Not formed | Not formed | Not formed | Not formed | Formed | Formed | Not formed | Not formed |
| Formed | Particulate | Formed | Formed | Formed | Formed | — | — | Not formed | Not formed |
| phase | structures a2 | | | | | | | | |
| structure | Average diameter D1 | 590 nm | 880 nm | 830 nm | 600 nm | — | — | 180 nm | — |
| | Average diameter D2 | 49 nm | 46 nm | 44 nm | 50 nm | — | — | — | — |
| | D2/D1 × 100 | 8.3% | 5.3% | 5.3% | 8.30% | — | — | — | — |

| | | | | | | | | |
|---|---|---|---|---|---|---|---|---|
| Particle-continued structures and/or | Formed | Formed | Formed | Formed | — | — | Not formed | Not formed |
| co-continuous-phase structures a3 | | | | | | | | |

As shown in Tables 1 and 2, and the figures, it is clear that in each of Examples 1 to 3, the thermosetting resin component A in the adhesive composition undergoes curing reaction, whereby: the component A is separated into particulate structures; pores are generated and/or the particulate structures partially undergo plastic deformation to be divided into fine fragments by expansion stress; and the thermosetting resin component A and the high-molecular component B are specifically separated from each other by spinodal decomposition.

The adhesive compositions of Examples 1 to 3, and the bonding member 4 of Example 4 are excellent in adhesive property, crack resistance, heat resistance, and exudation resistance.

From these matters, it is believed that support members for semiconductor mounting or semiconductor devices wherein the adhesive compositions of Examples 1 to 3, and the bonding member 4 of Example 4 are used are excellent in adhesive property, crack resistance, heat resistance, and exudation resistance.

On the other hand, in each of Comparative Examples 1 and 2, in the step of drying the adhesive composition, the epoxy resin is not cured; however, the composition gets white turbidity and is separated into the thermosetting resin component A (epoxy resin) and the high-molecular component B (acrylic copolymer) from each other. A bonding member using this has problems that the adhesive property is lowered in a B-stage state and the storage stability is remarkably lowered, and the like.

In Comparative Example 3, no particulate structures gather near the surface of the polyimide film, which is the adherend, so that the surface is hardly different from the inside region of the adhesive composition cured product. No structures based on a second-stage spinodal decomposition can be recognized, the structures being structures separated into the region b2, wherein the concentration of the high-molecular component is higher, and the particulate structures a2 and the particulate structures a4, wherein the concentration of the thermosetting resin component is higher. It is evident that the adherend-adhered sample bonding member VI is remarkably poor in adhesive property.

In Comparative Example 4, no particulate structures gather near the surface of the polyimide film, which is the adherend, so that the surface is hardly different from the inside region of the bonding member. No structures based on a second-stage spinodal decomposition can be recognized, the structures being structures separated into the region b2, wherein the concentration of the high-molecular component is higher, and the particulate structures a2 and the particulate structures a4, wherein the concentration of the thermosetting resin component is higher.

It is evident that the adherend-adhered sample bonding member VII is remarkably poor in adhesive property, crack resistance, heat resistance, and exudation resistance.

### INDUSTRIAL APPLICABILITY

According to the use of the adhesive composition of the invention, it is possible to provide an adhesive composition excellent in heat resistance, crack resistance, adhesive property, and exudation resistance, which is a property that the adhesive less exudes. The composition can be used also in thin-film bonding, wherein the thickness of the adhesive layer is set to 30 μm or less. The bonding member, support member for semiconductor mounting, and the semiconductor device wherein the adhesive composition is used also have the above-mentioned characteristics.

1. An adhesive composition, comprising, as essential components, a thermosetting resin component A and a high-molecular component B which are evenly compatible and miscible with each other at a temperature of 5 to 40° C. without being separated from each other, and a curing agent component C,
wherein after the adhesive composition comes into contact with an adherend and after the thermosetting resin component A is cured, the thermosetting resin component A is separated, in the adhesive composition, into particulate structures wherein the concentration of the thermosetting resin component A is larger than that in the surrounding of the particulate structures, and further the particulate structures are formed in a larger amount near a surface of the composition which contacts the adherend than inside the adhesive composition.

2. An adhesive composition, comprising, as essential components, a thermosetting resin component A and a high-molecular component B which are evenly compatible and miscible with each other at a temperature of 5 to 40° C. without being separated from each other, and a curing agent component C,
wherein after the adhesive composition comes into contact with an adherend and after the thermosetting resin component A is cured, the thermosetting resin component A is separated, in the adhesive composition, into particulate structures wherein the concentration of the thermosetting resin component A is larger than that in the surrounding of the particulate structures, the particulate structures are formed in a larger amount near a surface of the composition which contacts the adherend than inside the adhesive composition, and
a region where the concentration of the high-molecular component B is higher, the region being around the particulate structures formed near the composition surface contacting the adherend, has a nature that when the adherend is peeled, pores are generated partially in the region by expansion stress.

3. An adhesive composition, comprising, as essential components, a thermosetting resin component A and a high-molecular component B which are evenly compatible and miscible with each other at a temperature of 5 to 40° C. without being separated from each other, and a curing agent component C,
wherein after the adhesive composition comes into contact with an adherend and after the thermosetting resin component A is cured, the thermosetting resin component A is separated, in the adhesive composition, into particulate structures wherein the concentration of the thermosetting resin component A is larger than that in the surrounding of the particulate structures in the adhesive composition, the particulate structures are formed in a larger amount near a surface of the composition which contacts the adherend than inside the adhesive composition, and
the particulate structures formed near the composition surface contacting the adherend have a nature that when the adherend is peeled, the particulate structures partially undergo plastic deformation so as to be divided into fine fragments.

4. The adhesive composition according to claim 2 or 3, wherein a/the region where the concentration of the high-molecular component B is higher, the region being around the particulate structures formed near the composition surface contacting the adherend, has a nature that when the adherend is peeled, pores are generated partially in the region by expansion stress, and the particulate structures formed near the composition surface contacting the adherend have a nature that when the adherend is peeled, the particulate structures partially undergo plastic deformation so as to be divided into fine fragments.

5. The adhesive composition according to any one of claims 1 to 3, having the following relationship when the area fraction of the particulate structures to other regions in a section which is orthogonal to the adherend after the curing is represented by AF, the average diameter of the particulate structures is represented by D1, the area fraction of a region having distances of 0 to D1 from the composition surface contacting the adherend is represented by AF1, and the area fraction of a region having distances of D1 to D1×2 from the composition surface contacting the adherend is represented by AF2: AF1/AF2>1.05.

6. The adhesive composition according to any one of claims 1 to 3, wherein after the adhesive composition contacts the adherend and before the composition is cured, the thermosetting resin component A and/or the curing agent component C is/are higher in concentration in the region having distances of 0 to D1 which is the average diameter D1 of the particulate structures from the composition surface contacting the adherend than in the region having distances of D1 to D1×2 from the composition surface contacting the adherend.

7. An adhesive composition comprising, as essential components, a thermosetting resin component A and a high-molecular component B which are evenly compatible and miscible with each other at a temperature of 5 to 40° C. without being separated from each other, and a curing agent component C,
the composition having a nature that separation is made into the following in the adhesive composition after the adhesive composition comes into contact with an adherend and after the thermosetting resin component A is cured:
particulate structures a1 which are higher in the concentration of the thermosetting resin component A than the surrounding of the particulate structures al, and have an average diameter D1;
particulate structures a2 which are present in the particulate structures a1, have an average diameter D2 smaller than the average diameter D1, and are higher in the concentration of the thermosetting resin component A than the particulate structures a1;
a region b3 which is present in the particulate structures a1, is higher in the concentration of the high-molecular component B than the particulate structures a1, and is different from the particulate structures a2;
a region b2 which is higher in the concentration of the high-molecular component B than the particulate structures a1; and
particulate structures a4 which have an average diameter D6 smaller than the average diameter D1, and are higher in the concentration of the thermosetting resin component A than the region b2.

8. The adhesive composition according to claim 7, wherein the average diameter D1 and/or the average diameter D6 is/are 1 to 30% of the average diameter D1.

9. The adhesive composition according to claim 7, wherein the average diameter D2 and/or the average diameter D6 is/are 2 to 200 nm.

10. An adhesive composition comprising, as essential components, a thermosetting resin component A and a high-molecular component B which are evenly compatible and miscible with each other at a temperature of 5 to 40° C. without being separated from each other, and a curing agent component C,
the composition having a nature that separation is made into the following in the adhesive composition after the adhesive composition comes into contact with an adherend and after the thermosetting resin component A is cured:
particulate structures a1 which are higher in the concentration of the thermosetting resin component A than the surrounding of the particulate structures a1, and have an average diameter D1;
a region b2 which is higher in the concentration of the high-molecular component B than the particulate structures at and
particle-continued structures and/or co-continuous-phase structures a3 which are higher in the concentration of the thermosetting resin component A than the region b2, and have an average diameter D3 smaller than the average diameter D1 of the particulate structures a1.

11. The adhesive composition according to claim 10, wherein when the distance between the particulate structures a1 and the particle-continued structures and/or co-continuous-phase structures a3 is represented by the distance D4, the distance D4 is 10 to 90% of the average diameter D1.

12. The adhesive composition according to claim 10, wherein when the width between the particulate structures a1 and the particle-continued structures and/or co-continuous-phase structures a3 is represented by the width D5, the width D5 is 10 to 200% of the average diameter D1.

13. The adhesive composition according to any one of claims 1 to 3, 7 and 10, wherein the average diameter D1 of the particulate structures is 200 nm or more.

14. The adhesive composition according to any one of claims 1 to 3, 7 and 10, wherein the curing agent component C comprises a compound having an amino group.

15. The adhesive composition according to any one of claims 1 to 3, 7 and 10, wherein the curing agent component C comprises an aromatic amine compound.

16. The adhesive composition according to any one of claims 1 to 3, 7 and 10, wherein the thermosetting resin component A is an epoxy resin having two or more epoxy groups.

17. The adhesive composition according to claim 16, wherein the epoxy resin having two or more epoxy groups has a weight-average molecular weight less than 3,000.

18. The adhesive composition according to claim 16, wherein the epoxy resin having two or more epoxy groups has a weight-average molecular weight less than 1,500.

19. The adhesive composition according to claim 16, wherein the epoxy resin having two or more epoxy groups has polarity.

20. The adhesive composition according to claim 16, wherein the epoxy resin having two or more epoxy groups is a bisphenol A type epoxy resin.

21. The adhesive composition according to any one of claims 1 to 3, 7 and 10, wherein the high-molecular component B is an acrylic copolymer having a weight-average molecular weight of 100,000 or more.

22. The adhesive composition according to claim 21, wherein the high-molecular component B is an epoxy-group-containing acrylic copolymer containing, as a copolymerization component, glycidyl acrylate or glycidyl methacrylate in a proportion of 0.5 to 10% by mass, and having a glass transition temperature of −10° C. or higher.

23. The adhesive composition according to any one of claims 1 to 3, 7 and 10, wherein the high-molecular component B is contained in an amount of 100 to 900 parts by mass relative to 100 parts by mass of the thermosetting resin component A.

24. The adhesive composition according to any one of claims 1 to 3, 7 and 10, wherein the following are incorporated into a solvent: the thermosetting resin component A; the high-molecular component B, the amount of which is 100 to 900 parts by mass relative to 100 parts by mass of the thermosetting resin component A; and the curing agent component C, the amount of which is 0.5 to 2 times the chemical equivalent of the thermosetting resin component A.

25. A bonding member containing an adhesive layer obtained by forming an adhesive composition as recited in any one of claims 1 to 3, 7 and 10 into a film form.

26. A process for producing a bonding member, comprising the steps of:
painting an adhesive composition as recited in any one of claims 1 to 3, 7 and 10 onto a film as an adherend;
heating and drying the resultant to form a painted film of the adhesive composition; and
covering the painted film of the adhesive composition with another film.

27. A support member for semiconductor mounting, comprising a bonding member as recited in claim 25 over a semiconductor element mounted surface of a support member.

28. A process for producing a support member for semiconductor mounting, wherein a bonding member as recited in claim 25 is adhered onto a semiconductor element mounted surface of a support member.

29. A semiconductor device, wherein a bonding member as recited in claim 25 is used to bond a semiconductor element and a support member to each other.

30. A semiconductor device, wherein a support member for semiconductor mounting as recited in claim 27 is used.

31. A process for producing a semiconductor device, comprising the steps of:
bonding a semiconductor element and a support member to each other by using a bonding member as recited in claim 25; and
connecting electrodes of the semiconductor element and a wiring board which becomes the support member to each other by wire bonding or inner lead bonding of tape automated bonding.

32. The process for producing a semiconductor device according to claim 31, wherein said support member is a support member for semiconductor mounting including said bonding member over a semiconductor element mounted surface of the support member for semiconductor mounting.
